(19) United States
(12) Patent Application Publication
(10) Pub. No.: US 2024/0222199 A1
(43) Pub. Date: Jul. 4, 2024

(54) DEVICE AND METHOD FOR SORTING SEMICONDUCTOR CHIP WITH POTENTIAL FAILURE RISK

(71) Applicant: Samsung Electronics Co., Ltd., Suwon-si (KR)

(72) Inventors: Gooyoung Kim, Suwon-si (KR); Youngseon Moon, Suwon-si (KR); Myoungho Son, Suwon-si (KR); Jueun Hwang, Suwon-si (KR)

(73) Assignee: Samsung Electronics Co., Ltd., Suwon-si (KR)

(21) Appl. No.: 18/370,139

(22) Filed: Sep. 19, 2023

(30) Foreign Application Priority Data
Dec. 28, 2022 (KR) 10-2022-0187767
Feb. 15, 2023 (KR) 10-2023-0020128

(51) Int. Cl. H01L 21/66; G01R 31/28; H01L 21/67

(52) U.S. Cl. CPC H01L 22/12; G01R 31/2831; H01L 21/67271; H01L 22/20

(57) ABSTRACT

A device for sorting semiconductor chips with potential failure risk includes a memory and a processor that generates a test result map and a distance map from an inspection result of a wafer, calculates a potential failure risk value of a target semiconductor chip that is determined as an inspection pass, based on the test result map and the distance map, and sorts the target semiconductor chip with potential failure risk based on the potential failure risk value.

### CROSS-REFERENCE TO RELATED APPLICATIONS

This application is based on and claims priority under 35 U.S.C. § 119 to Korean Patent Application No. 10-2022-0187767, filed on Dec. 28, 2022, and Korean Patent Application No. 10-2023-0020128, filed on Feb. 15, 2023, in the Korean Intellectual Property Office, the disclosures of each of which being incorporated by reference herein in their entireties.

### BACKGROUND

The present disclosure relates to an electronic device, and more particularly, to a device and method for sorting a semiconductor chip with potential failure risk.

Semiconductor chips are formed in a wafer by using several types of processes. During the processes, several types of process defects may occur in a wafer. The process defects may be factors in reducing the yield of semiconductor chips.

In order to determine whether various process defects occur, a wafer test may be performed on the semiconductor chips. A semiconductor chip that passes the wafer test may be classified as a good chip, and a semiconductor chip that fails the wafer test is classified as a failed chip.

However, in some cases, a semiconductor chip with low quality and high potential failure risk may pass the wafer test due to a test error.

### SUMMARY

It is an aspect to provide a device and a method for more accurately determining the degree of risk of a semiconductor chip passed a test by using inspection result values of a corresponding chip and peripheral chips together with a distance value.

According to an aspect of one or more embodiments, there is provided a device comprising a memory storing instructions for performing a method of sorting semiconductor chips with potential failure risk from a wafer of which inspection is completed; and a processor configured to execute the instructions to cause the processor to at least acquire a test result map including test result values for each semiconductor chip of a plurality of semiconductor chips included in the wafer from an inspection result of the wafer, generate a distance map including a distance value between a target semiconductor chip determined as an inspection pass among the plurality of semiconductor chips and one or more peripheral semiconductor chips of the target semiconductor chip in at least one coordinate system, calculate a potential failure risk value of the target semiconductor chip based on the test result map and the distance map, and determine whether the target semiconductor chip has the potential failure risk based on the potential failure risk value.

According to another aspect of one or more embodiments, there is provided a method comprising inspecting a wafer including a plurality of semiconductor chips by performing a test according to each of a plurality of test items; generating a bit map including a bit value indicating whether the plurality of semiconductor chips fail at least one test item among the plurality of test items, based on an inspection result of the wafer; generating a distance map including a distance value between a target semiconductor chip determined as an inspection pass among the plurality of semiconductor chips and one or more peripheral semiconductor chips around the target semiconductor chip in at least one coordinate system; calculating a potential failure risk value of the target semiconductor chip based on the bit map and the distance map; and sorting whether the target semiconductor chip has potential failure risk based on the potential failure risk value.

According to yet another aspect of one or more embodiments, there is provided a method comprising inspecting a wafer including a plurality of semiconductor chips by performing a test according to each of a plurality of test items; generating a defective count map including an integer value indicating a number of failed components included in a semiconductor chip that failed at least one of the plurality of test items among the plurality of semiconductor chips, based on an inspection result of the wafer; generating a distance map including a distance value between a target semiconductor chip determined as inspection pass among the plurality of semiconductor chips and one or more peripheral semiconductor chips around the target semiconductor chip in at least one coordinate system; calculating a potential failure risk value of the target semiconductor chip based on the defective count map and the distance map; and sorting whether the target semiconductor chip has potential failure risk based on the potential failure risk value.

According to yet another aspect of one or more embodiments, there is provided a device comprising a memory storing instructions for performing a method of sorting a semiconductor chip with potential failure risk in a wafer group including a plurality of wafers which are stacked; and a processor configured to execute the instructions to cause the processor to at least acquire a test result map, which includes test result values for each of a plurality of semiconductor chips included in each of the plurality of wafers, from an inspection result of the wafer group, generates a distance map in at least one three-dimensional coordinate system, the distance map including a distance value between a target semiconductor chip determined as an inspection pass among the plurality of semiconductor chips and one or more peripheral semiconductor chips included in a same wafer as the target semiconductor chip and a distance value between the target semiconductor chip and one or more peripheral semiconductor chips included in a peripheral wafer, in the at least one three-dimensional coordinate system, calculates a potential failure risk value of the target semiconductor chip based on the test result map and the distance map, and determines whether the target semiconductor chip has the potential failure risk based on the potential failure risk value.

### BRIEF DESCRIPTION OF THE DRAWINGS

Various embodiments will be more clearly understood from the following detailed description taken in conjunction with the accompanying drawings, in which:

FIG. 1 is a diagram illustrating a system according to some embodiments;

FIG. 2 is a view illustrating a wafer according to some embodiments;

FIG. 3 is a flowchart illustrating a method that is performed by a device of FIG. 1, according to some embodiments;

FIG. 4 is a diagram illustrating an example of a test result map, according to some embodiments;

FIG. 5 is a diagram illustrating an example of a test result map, according to some embodiments;

FIG. 6 is a flowchart illustrating the method of FIG. 3, according to some embodiments;

FIG. 7 is a diagram illustrating an example of a street map, according to some embodiments;

FIG. 8 is a diagram illustrating coordinates and distances in a Cartesian coordinate system by way of example;

FIG. 9 is a diagram illustrating coordinates and distances in a polar coordinate system by way of example;

FIG. 10 is a diagram illustrating coordinates and distances in a photo shot coordinate system by way of example;

FIG. 11 is a diagram illustrating an example of generating a kernel smoothing map, according to some embodiments;

FIG. 12 is a diagram illustrating an example of a test result map and a kernel smoothing map, according to some embodiments;

FIG. 13 is a diagram illustrating an example of generating a kernel smoothing map, according to some embodiments;

FIG. 14 is a diagram illustrating an example of a test result map and a kernel smoothing map, according to some embodiments;

FIG. 15 is a diagram illustrating an example of generating a final kernel smoothing map, according to some embodiments;

FIG. 16 is a diagram illustrating an example of a test result map and a kernel smoothing map, according to some embodiments;

FIG. 17 is a diagram illustrating an example of generating a final kernel smoothing map, according to some embodiments;

FIG. 18 is a diagram illustrating an example of a test result map and a kernel smoothing map, according to some embodiments;

FIG. 19 illustrates wafer models for each map type, according to some embodiments;

FIG. 20 is a flowchart illustrating a method according to some embodiments;

FIG. 21 is a flowchart illustrating an example of operation S2020 of FIG. 20, according to some embodiments;

FIG. 22 is a flowchart illustrating an example of operation S2030 and an operation S2040 of FIG. 20, according to some embodiments;

FIG. 23 is a flowchart illustrating an example of operation S2211 of FIG. 22, according to some embodiments;

FIG. 24 is a flowchart illustrating an example of operation S2212 of FIG. 22, according to some embodiments;

FIG. 25 is a flowchart illustrating an example of operation S2213 of FIG. 22, according to some embodiments;

FIG. 26 is a flowchart illustrating a method, according to some embodiments;

FIG. 27 is a flowchart illustrating an example of operation S2620 of FIG. 26, according to some embodiments;

FIG. 28 is a diagram illustrating a system according to some embodiments; and

FIG. 29 is a diagram illustrating a map in a three-dimensional coordinate system, according to some embodiments.

### DETAILED DESCRIPTION

A plurality of semiconductor chips may be formed in a wafer by using several types of processes. The plurality of semiconductor chips may be regularly arranged in the wafer. During the processes, several types of process defects may occur in a wafer. The process defects may be factors in reducing the yield of semiconductor chips.

In order to determine whether various process defects occur, a wafer test according to a plurality of test items may be performed on a plurality of semiconductor chips. A semiconductor chip that passes all of a plurality of test items may be classified as a good chip. A semiconductor chip that fails at least one of the plurality of test items is classified as a failed chip.

However, a semiconductor chip with low quality and high potential failure risk may pass a wafer test due to a test error and may be transferred to a subsequent process or to a customer. An additional sorting method or work may be required to address this problem. Due to characteristics of a manufacturing process performed in units of wafers (or lots), characteristics of semiconductor chips located close to each other in a wafer may be similar to each other. Accordingly, there is a method of additionally determining the degree of risk of a preset semiconductor chip based on an average yield of semiconductor chips adjacent to the specific semiconductor chip that have passed a wafer test. However, this method has a limitation in accuracy in that only an average yield of adjacent semiconductor chips or whether the semiconductor chips pass the test is considered.

In order to increase the accuracy of determination, there is a need for a method of determining the risk of a semiconductor chip that has passed a test by using various types of information of semiconductor chips in a wider peripheral region and adjacent semiconductor chips.

Hereinafter, embodiments are described in detail with reference to the accompanying drawings.

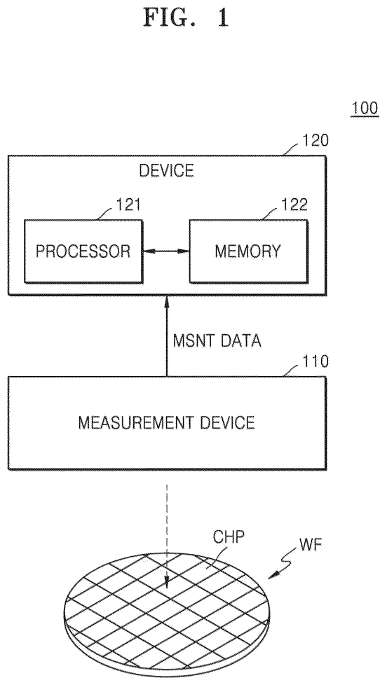

FIG. 1 is a diagram illustrating a system 100 according to some embodiments.

Referring to FIG. 1, the system 100 may inspect a wafer WF by performing a test on the wafer WF according to a plurality of test items and may sort failed semiconductor chips from the wafer WF of which inspection is completed.

The wafer WF may include one or more semiconductor chips CHP. A semiconductor chip CHP may be a memory chip or a non-memory chip. The memory chip may be a non-volatile memory chip or a volatile memory chip. A memory chip may include a cell region and a peripheral region. The cell region may include a plurality of memory cells. The plurality of memory cells may be at positions where a plurality of bit lines cross a plurality of word lines. The plurality of memory cells may be included in a plurality of memory blocks. The peripheral region may include components other than components in the cell region of the memory chip. For example, a peripheral region of a nonvolatile memory chip may include a control logic, a page buffer, a row decoder, a voltage generator, and so on. In some embodiments, a peripheral region of a volatile memory chip may include a control logic, a row decoder, a column decoder, a sense amplifier, a refresh control logic, a bank control logic, and so on. Herein, a “chip” may be referred to as a “die”.

Herein, “inspection” denotes checking whether a product is properly manufactured according to specifications during a process of manufacturing the product. Herein, “inspection completion” denotes that testing of all of a plurality of test items is completed. Herein, an “inspection result” may include an inspection pass or an inspection failure. Herein, “inspection pass” denotes that a product passes the test of all of a plurality of test items. Herein, “inspection failure” denotes that a product fails the test of at least one of the plurality of test items.

Herein, “test” denotes that specifications are actually performed one by one to check whether products are manufactured according to the specifications. The specifications may be required by customers. Herein, “test completion” denotes that a test of a specific test item is completed and a test result is generated. Herein, “test pass” denotes that a test of individual test items is passed, a test of at least some test items is passed, or a test of all test items is passed. Herein, “test failure” denotes that a test of individual test items is failed, a test of at least some test items is failed, or a test of all test items is failed.

Test items may be divided into test items related to memory chips and test items related to non-memory chips. Test items for memory chips or non-memory chips may be divided into test items for the chip itself and test items for a specific component included in the chip. Test items for a specific component of a memory chip may be divided into testing a cell region of the memory chip and testing a peripheral region of the memory chip.

A measurement device 110 may actually measure the wafer WF and output measurement data MSNT DATA. When there are a plurality of wafers WF, the measurement device 110 may measure characteristics of the wafers WF. In some embodiments, the measurement device 110 may irradiate the wafer WF with light and provide the measurement data MSNT DATA to a device 120. In some embodiments, the measurement device 110 may apply a test current (or a test voltage) to each of semiconductor chips CHP and output the measurement data MSNT DATA including a value of an output current (or an output voltage). In some embodiments, the measurement device 110 may also output the measurement data MSNT DATA to be used for an electrical die sorting (EDS) test.

The measurement device 110 may perform optical critical dimension (OCD) measurement, electron beam (e-beam) measurement, x-ray measurement, device characteristic measurement, and so on.

The device 120 may include a computing device, such as a server, a personal computer, a laptop computer, a portable communication terminal, a smartphone, or so on.

The device 120 may receive the measurement data MSNT DATA from the measurement device 110. The device 120 may inspect the wafer WF by using the measurement data MSNT DATA. The device 120 may sort a semiconductor chip with potential failure risk from the wafer WF of which inspection is completed. In some cases, there may be more than one semiconductor chip with potential failure risk. That is, the device 120 may sort one or more semiconductor chips with potential failure risk from the wafer WF.

A semiconductor chip with potential failure risk may be a semiconductor chip evaluated as a good product but with potential failure risk. When a semiconductor chip with potential failure risk is provided to a subsequent process or a customer, the semiconductor chip is very likely to be a failed chip. Accordingly, there may be problems, such as an increase in cost of a subsequent process or a decrease in customer satisfaction.

In order to sort a semiconductor chip with potential failure risk at an early stage, the device 120 may include a processor 121 and a memory 122.

The processor 121 may control all operations of the device 120. The processor 121 may include an accelerator that is a dedicated circuit for data calculation. The accelerator may be a functional block that professionally performs a specific function of the processor 121. The accelerator may include a graphics processing unit (GPU), a neural processing unit (NPU), or a data processing unit (DPU). The GPU may be a block for professionally processing graphics data. The NPU may be a block for professionally performing artificial intelligence (AI) calculation and inference. The DPU may be a block for professionally performing data transmission.

The processor 121 may execute instructions stored in the memory 122.

In some embodiments, the processor 121 may test a plurality of semiconductor chips included in the wafer WF according to a plurality of test items according to the instructions. Here, a test sequence of a plurality of test items may be determined in advance. That is, a test of a specific test item may be performed, and after the test of the specific test item is completed, a test of another test item may be performed. In this case, when there is a semiconductor chip CHP in which the test of a test item preceding the specific test item failed, a test of a subsequent test item may be stopped. Columns for test results of subsequent test items may be blank (for example, N/A: not applicable, not available, or no answer).

In some embodiments, the processor 121 may perform a method of sorting semiconductor chips with potential failure risk from the wafer WF of which inspection is completed through instructions.

The processor 121 may include a test module for testing the semiconductor chip CHP and a sorting module for sorting a semiconductor chip with potential failure risk from the wafer WF of which inspection is completed.

The memory 122 may include instructions for performing a method of testing a plurality of semiconductor chips according to a plurality of test items. The memory 122 may store instructions for performing a method of sorting semiconductor chips with potential failure risk from the wafer WF of which inspection is completed. Instructions may be stored in the memory 122 as code of a computer program.

The memory 122 may store coordinate system data for calculating positions of the wafer WF and/or the semiconductor chip CHP. The coordinate system data may include a wafer map corresponding to the wafer WF.

In some embodiments, the memory 122 may include a non-volatile memory, such as read-only memory (ROM), magnetic random access memory (MRAM), spin-transfer torque MRAM, conductive bridging RAM (CBRAM), ferroelectric RAM (FeRAM), phase RAM (PRAM), or resistive RAM. However, the memory 122 is not limited thereto.

In other embodiments, the memory 122 may include dynamic RAM (DRAM), synchronous DRAM (SDRAM), double data rate SDRAM (DDR SDRAM), low power double data rate SDRAM (LPDDR SDRAM), graphics double data rate SDRAM (GDDR SDRAM), DDR2 SDRAM, DDR3 SDRAM, DDR4 SDRAM, DDR5 SDRAM, or so on. However, the memory 122 is not limited thereto.

As described above, by sorting a potential failure semiconductor chip, an effect of reducing costs to be consumed in a subsequent process and various failed products to be provided to customers may be obtained.

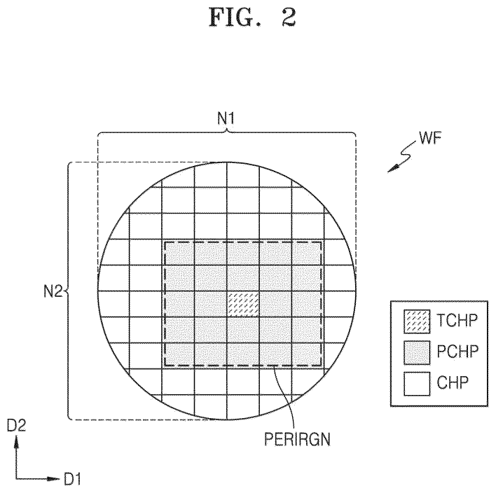

FIG. 2 is a view illustrating a wafer WF according to some embodiments.

Referring to FIG. 2, the wafer WF may include one or more semiconductor chips CHP. The wafer WF may have a circular shape. One or more semiconductor chips CHP may be arranged in the wafer WF in a first direction D1. The greatest number of semiconductor chips CHP arranged in the wafer WF in the first direction D1 may be N1. N1 may be an integer that is greater than or equal to 1. Hereinafter, the greatest number of semiconductor chips CHP arranged in the wafer WF in the first direction D1 may be referred to as a first integer value.

One or more semiconductor chips CHP arranged in the wafer WF in the first direction D1 may be arranged in a second direction D2. The second direction D2 may be perpendicular to the first direction D1. The greatest number of semiconductor chips CHP arranged in the wafer WF in the second direction D2 may be N2. N2 may be an integer that is greater than or equal to 1. Hereinafter, the greatest number of semiconductor chips CHP arranged in the wafer WF in the second direction D2 may be referred to as a second integer value.

In some embodiments, the first integer value (for example, N1) may be equal to the second integer value (for example, N2). In some embodiments, the first integer value (for example, N1) may be different from the second integer value (for example, N2).

A target semiconductor chip TCHP may be a chip determined as inspection pass among a plurality of semiconductor chips included in the wafer WF of which inspection is completed. The “target semiconductor chip” may be referred to as a die under investigation (DUI).

Peripheral semiconductor chips PCHP may be around the target semiconductor chip TCHP among a plurality of semiconductor chips. The peripheral semiconductor chips PCHP may include not only chips physically adjacent to the target semiconductor chip TCHP, but also chips separated from the target semiconductor chip TCHP by a distance. The distance may be preset. The number of peripheral semiconductor chips PCHP may be determined in advance according to a peripheral range PERIRGN. For example, the number of peripheral semiconductor chips PCHP around the target semiconductor chip TCHP may be 8, and the peripheral range PERIRGN may be a size of 3×3. However, the embodiments are not limited thereto. In some embodiments, the peripheral semiconductor chips PCHP may include semiconductor chips of the wafer WF of which inspection is completed other than the target semiconductor chip TCHP.

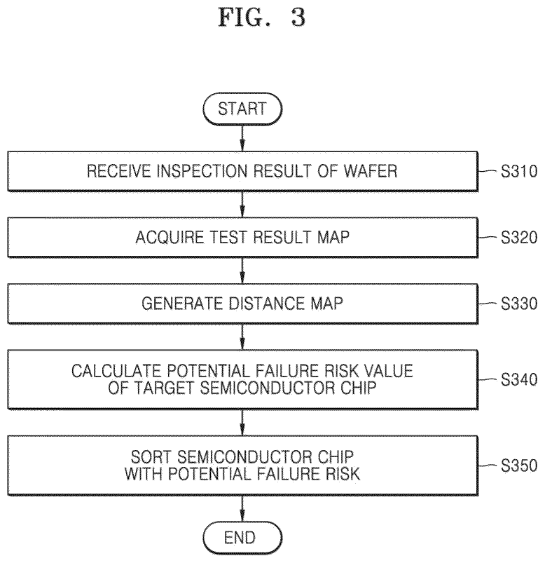

FIG. 3 is a flowchart illustrating a method performed by the device 120 of FIG. 1, according to some embodiments;

Referring to FIGS. 1, 2, and 3, the method of FIG. 3 may be performed by the processor 121 and may sort a semiconductor chip with potential failure risk from an inspected wafer. The method of FIG. 3 may include operations S310, S320, and S330.

In operation S310, the processor 121 may receive an inspection result of the wafer WF. For example, the processor 121 may include a test module and a sorting module, and the sorting module may receive the inspection result from the test module.

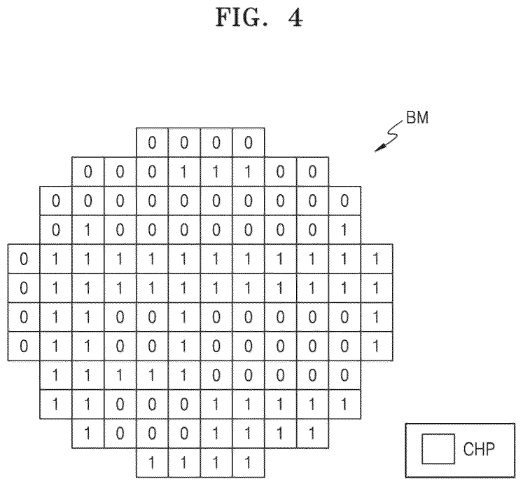

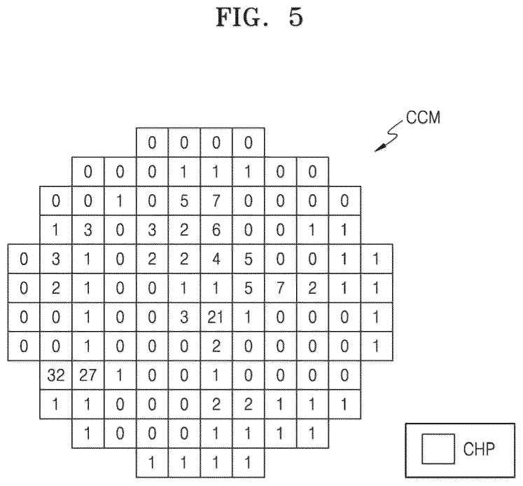

In operation S320, the processor 121 may acquire a test result map from an inspection result of the wafer WF. The test result map may include a test result value for each semiconductor chip CHP. The test result value may be a value indicating a test result of the semiconductor chip CHP. Because the wafer WF includes a plurality of semiconductor chips, the test result map may also include a plurality of test result values. An example of the test result is described below with reference to FIGS. 4 and 5, according to some embodiments.

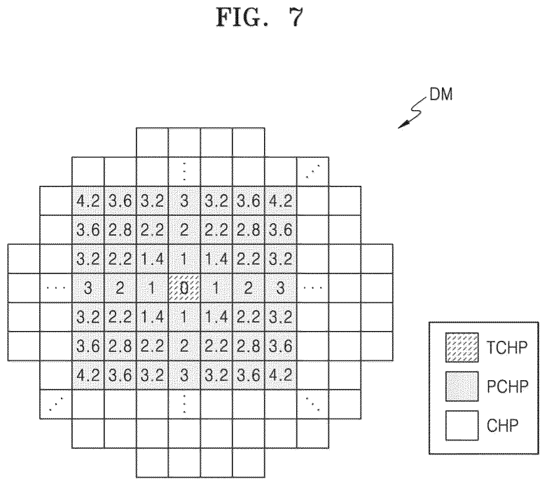

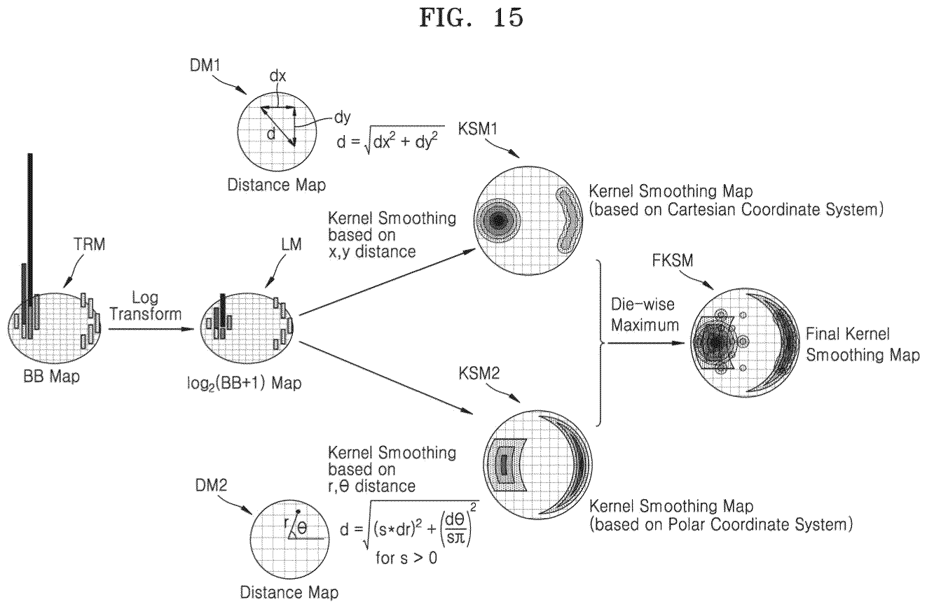

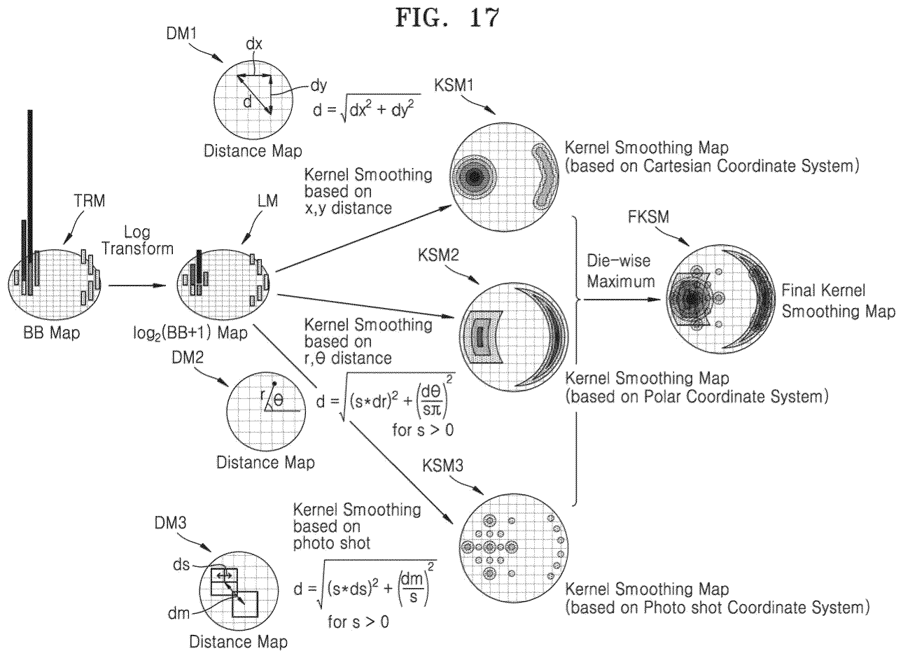

In operation S330, the processor 121 may generate a distance map by using an inspection result of the wafer WF, a test result map, and/or coordinate system data. At least one distance map may include distance values. A distance value of one distance map may indicate a distance from the target semiconductor chip TCHP to the semiconductor chip PCHP adjacent thereto in one coordinate system. The target semiconductor chip TCHP may be a chip determined as an inspection pass among a plurality of semiconductor chips. The distance value may be calculated by using coordinate values of a specific coordinate system. Because there may be one or more peripheral semiconductor chips PCHP, the distance map may include one or more distance values. An example of the distance map is described below with reference to FIG. 7, according to some embodiments. The distance map may be generated for each coordinate system being used. A distance map of the target semiconductor chip TCHP generated for each coordinate system is described below with reference to FIGS. 15 and 17, according to some embodiments.

In operation S340, the processor 121 may calculate a potential failure risk value of the target semiconductor chip TCHP. For example, the processor 121 may calculate the potential failure risk value of the target semiconductor chip TCHP based on the test result map and the distance map. The potential failure risk value may potentially indicate the degree of risk of the target semiconductor chip TCHP.

In operation S350, the processor 121 may sort whether the target semiconductor chip TCHP has a potential failure risk, based on the potential failure risk value. Specifically, for example, when the potential failure risk value is greater than a reference value, the processor 121 may determine that the target semiconductor chip TCHP has potential failure risk. The reference value may be preset, or may be set experimentally. When the potential failure risk value is less than or equal to the reference value, the processor 121 may determine that the target semiconductor chip TCHP is a good chip.

A semiconductor chip with potential failure risk may be screened during a process. Good chips may be handled as a flow in the process. In some embodiments, subsequent to operation S350, the processor 121 may retest the semiconductor chip with potential failure risk.

FIG. 4 is a diagram illustrating an example of a test result map, according to some embodiments.

Referring to FIG. 4, the test result map may be included in a test result. In some embodiments, the test result map may be implemented as a bit map BM including single-bit values. The single-bit values may indicate a test pass or a test failure on the semiconductor chip CHP.

Specifically, for example, the bit map BM may be a first bit map including single-bit values indicating a test result of each of the semiconductor chips CHP. The test result of the semiconductor chip CHP may indicate whether the semiconductor chip CHP passes or fails the test for all test items or for individual test items. For example, a single-bit value indicating a test pass of the semiconductor chip CHP may be 0 and a single-bit value indicating a test failure of the semiconductor chip CHP may be 1. However, the embodiments are not limited thereto.

In some embodiments, specifically, the bit map BM may be a second bit map including a single-bit value indicating a test result of a component included in the semiconductor chip CHP. The component included in the semiconductor chip CHP may include a memory cell, a memory block, a word line, a bit line, and so on, which are included in a cell region of the semiconductor chip CHP. In some embodiments, the component included in the semiconductor chip CHP may include components included in a peripheral region of the semiconductor chip CHP. In some embodiments, the component included in the semiconductor chip CHP may include functional components of the non-memory chip. A test result of the component may indicate whether the component passes or fails the test for all test items or for individual test items. For example, a single-bit value indicating a test pass of the component may be 0 and a single-bit value indicating a test failure of the semiconductor chip CHP may be 1. The value 0 or 1, which is a single-bit value of the bitmap BM, may be a valid value.

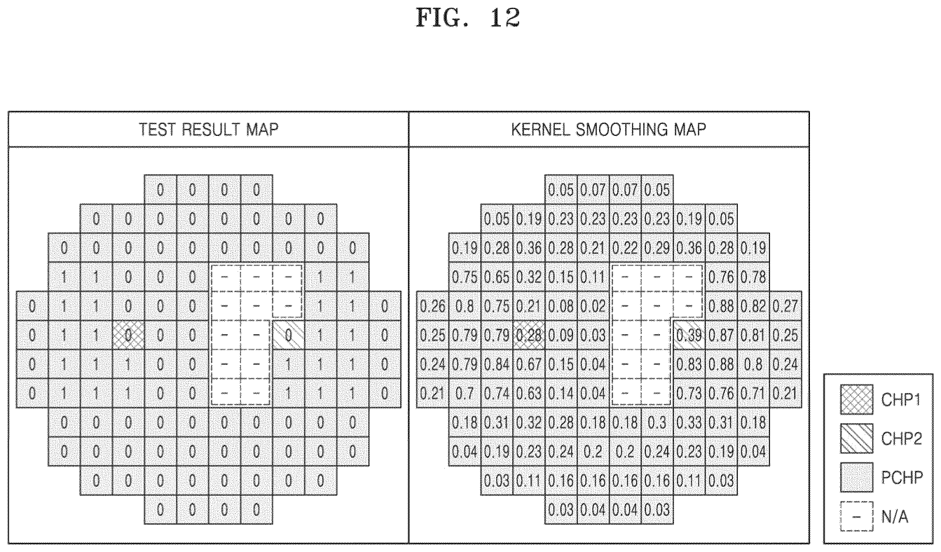

In some embodiments, the bitmap BM may include a blank (for example, N/A) in which a single-bit value is missing. An example of the bit map BM including a blank is described below with reference to FIG. 12.

FIG. 5 is a diagram illustrating an example of a test result map, according to some embodiments.

Referring to FIG. 5, in some embodiments, the test result map may be implemented as a defective count map CCM including integer values. The integer values may indicate a number of failed components included in the semiconductor chip CHP. The failed components may each include, for example, a weak cell, a bad block, a bad word line, and a bad bit line.

Specifically, for example, 0 of integer values of the defective count map CCM may be a valid value.

In some embodiments, the defective count map CCM may include a blank (for example, N/A) in which an integer value is missing. An example of the defective count map CCM including a blank is described below with reference to FIG. 12.

Referring to FIGS. 1, 4, and 5, the processor 121 may acquire one of a bit map BM and the defective count map CCM as a test result map.

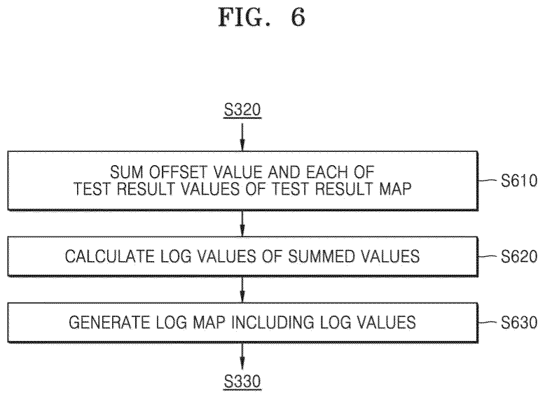

FIG. 6 is a flowchart illustrating an example of the method of FIG. 3, according to some embodiments.

Referring to FIGS. 1, 3, and 6, in some embodiments, the processor 121 may convert the test result map into a log map. The reason for converting the test result map to the log map is to reflect an increase rate of potential failure risk due to an increase in the number of failed semiconductor chips CHP or the number of failed components of the semiconductor chip CHP, in calculating a potential failure risk value. After operation S320 of FIG. 3, operation S610 may be performed.

In operation S610 performed subsequently to operation S320, the processor 121 may add an offset value to each of test result values of a test result map. Here, the test result map may be the bit map BM of FIG. 4 or the defective count map CCM of FIG. 5.

In operation S620, the processor 121 may calculate log values for the summed values. In this case, a value summed in a log calculation is a real number of a log and a base of the log may be a positive number other than 1. In some embodiments, a common log, which is the base of the log, may be used.

In operation S630, the processor 121 may generate a log map including log values. The log map may be used to calculate a potential failure risk value instead of a test result map. That is, the processor 121 may calculate the potential failure risk value based on the log map and the distance map. Following operation S630, the method may proceed to operation S330 of FIG. 3.

FIG. 7 is a diagram illustrating an example of a distance map DM, according to some embodiments.

Referring to FIG. 7, the distance map DM may include distance values. As illustrated in FIG. 7, some distance values may be approximate values indicating values up to one decimal place but embodiments are not limited thereto.

When the number of peripheral semiconductor chips PCHP increases, the number of distance values may also increase. Because the distance value indicates a distance from a target semiconductor chip TCHP to a peripheral semiconductor chip PCHP based on the target semiconductor chip TCHP, the distance values displayed on a distance map in FIG. 7 may be values that are relatively changed according to the target semiconductor chip TCHP. In other words, as the target semiconductor chip TCHP changes, the distance values in the distance map will change.

In some embodiments, the processor 121 may calculate distance values for each peripheral semiconductor chip PHP, based on first coordinate values and second coordinate values indicating positions of a plurality of semiconductor chips in at least one two-dimensional coordinate system among various types of two-dimensional coordinate systems. The two-dimensional coordinate system may be, for example, a Cartesian coordinate system, a polar coordinate system, or a photo shot coordinate system. However, the two-dimensional coordinate system is not limited thereto. Hereinafter, an example of calculating a distance value in each two-dimensional coordinate system is described below.

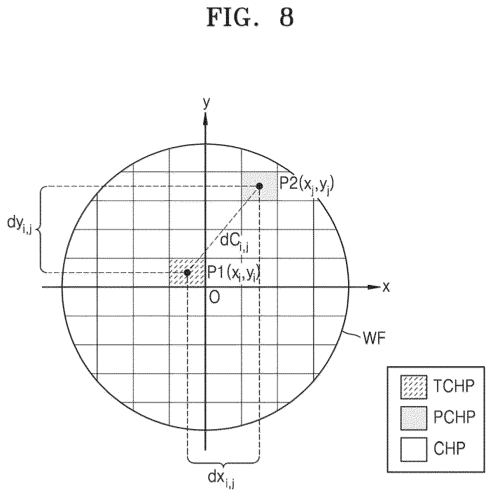

FIG. 8 is a diagram illustrating coordinates and distances in a Cartesian coordinate system by way of example.

Referring to FIG. 8, the Cartesian coordinate system may be a coordinate system composed of an x axis and a y axis. In this case, a first coordinate value and a second coordinate value according to the Cartesian coordinate system may include an x-axis value and a y-axis value. For example, the first coordinate value of the Cartesian coordinate system may be an x-axis value, and the second coordinate value of the Cartesian coordinate system may be a y-axis value.

In some embodiments, the origin O of the Cartesian coordinate system may be a coordinate corresponding to the center of the wafer WF when the wafer WF is assumed to be a concentric circle on a coordinate plane. However, the origin O is not limited thereto. In some embodiments, the origin O of the Cartesian coordinate system may be a coordinate corresponding to the center of a certain semiconductor chip CHP.

A first point P1 (xᵢ,yᵢ) may be a coordinate indicating a position of the target semiconductor chip TCHP. A first coordinate value of the first point P1(xᵢ,yᵢ) may be xᵢ and a second coordinate value of the first point P1(xᵢ,yᵢ) may be yᵢ. i may be any natural number.

A second point P2(xⱼ,yⱼ) may be a coordinate indicating a position of a certain peripheral semiconductor chip PCHP. A first coordinate value of the second point P2(xⱼ,yⱼ) may be xⱼ and a second coordinate value of the second point P2(xⱼ,yⱼ) may be yⱼ. j is a natural number different from i among natural numbers from 1 to N, and N may be the number of peripheral semiconductor chips PHP.

In some embodiments, as illustrated in FIG. 2, when a first integer value (for example, N1) is equal to a second integer value (for example, N2), a distance value dC_{i,j} between the target semiconductor chip TCHP and the certain peripheral semiconductor chip PCHP may be calculated according to Equation 1 below.

$$for i , j = 1 , 2 , ... , N ( = netdie ) \qquad Equation 1$$

$${dC}_{i , j} = \sqrt{{dx}_{i , j}^{2} + {dy}_{i , j}^{2}}$$

$$where$$

$${dx}_{i , j} = \vert {x}_{i} - {x}_{j} \vert , {dy}_{i , j} = \vert {y}_{i} - {y}_{j} \vert$$

Here, dx_{i,j} denotes a difference value between the first coordinate values and dy_{i,j} denotes a difference value between the second coordinate values.

In some embodiments, the first integer value (for example, N1) may be different from the second integer value (for example, N2). In this case, even when a distance between two coordinates is equal to a distance between another two coordinates, movement amounts from one coordinate to another coordinate may be different from each other. Therefore, it is advantageous to correct a current coordinate to a corrected coordinate by using the greatest number of each direction.

In some embodiments, the processor 121 may calculate the first correction coordinate value by calculating a ratio of the first coordinate value with respect to the first integer value (for example, N1). The processor 121 may calculate a second correction coordinate value by calculating a ratio of the second coordinate value with respect to the second integer value (for example, N2). The processor 121 may calculate a distance value based on the first correction coordinate value and the second correction coordinate value.

The first correction coordinate value x′ and the second correction coordinate value y′ may be calculated according to Equation 2 below.

$${x}^{′} = \frac{x}{N 1} , {y}^{′} = \frac{y}{N 2} \qquad Equation 2$$

Here, x is the first coordinate value, N1 is the first integer value, y is the second coordinate value, and N2 is the second integer value.

Coordinates of the first point P1(xᵢ,yᵢ) and the second point P2(xⱼ,yⱼ) may be corrected according to Equation 2 described above, and a distance value between the corrected coordinates may be calculated according to Equation 1.

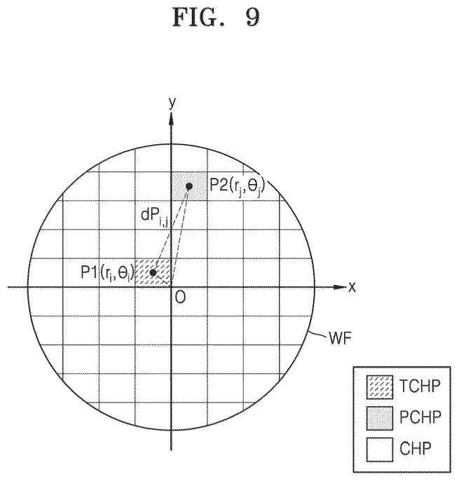

FIG. 9 is a diagram illustrating coordinates and distances in a polar coordinate system by way of example.

Referring to FIG. 9, a first coordinate value of a polar coordinate system is a value r indicating a distance from the origin O and a second coordinate value of the polar coordinate system may be a value θ indicating an angle formed in a counterclockwise direction from the x axis.

In some embodiments, the origin O of the polar coordinate system may be a coordinate corresponding to the center of the wafer WF when the wafer WF is assumed to be a concentric circle on a coordinate plane. However, the origin is not limited thereto. In some embodiments, the origin O of the polar coordinate system may be a coordinate corresponding to the center of a certain semiconductor chip CHP.

A first point P1(rᵢ,θᵢ) may be a coordinate indicating a position of the target semiconductor chip TCHP. In addition, a second point P2(rⱼ,θⱼ) may be a coordinate indicating a position of a certain peripheral semiconductor chip PCHP.

In some embodiments, a distance value dP_{i,j} between the target semiconductor chip TCHP and the certain peripheral semiconductor chip PCHP may be calculated according to Equation 3 below.

$$for i , j = 1 , 2 , ... , N ( = netdie ) \qquad Equation 3$$

$${dP}_{i , j} = \sqrt{{dr}_{i , j}^{2} + {( \frac{d {θ}_{i , j}}{π} )}^{{2}^{}}}$$

$$where$$

$${dr}_{i , j} = \vert {r}_{i} - {r}_{j} \vert , d {θ}_{i , j} = min ( \vert {θ}_{i} - {θ}_{j} \vert , 2 π - \vert {θ}_{i} - {θ}_{j} \vert )$$

$$( d {θ}_{i , j} = 0 if {θ}_{i} or {θ}_{j} is undefined )$$

Here, dr_{i,j} denotes a difference value between the first coordinate values and dθ_{i,j} denotes a smallest difference value between the second coordinate values. dr_{i,j} may be referred to as a first difference value in a polar coordinate system. dθ_{i,j} may be referred to as a second difference value in the polar coordinate system.

In some embodiments, a wafer manufacturing process may include various manufacturing processes, and for example, a wafer process may include processes, in which processes are performed while rotating the wafer WF, such as a chemical mechanical polishing (CMP) process and a photoresist (PR) development process. In some embodiments, the wafer process may include a process in which a chemical substance acts in a direction perpendicular to a surface of the wafer WF, such as an etch process. As described above, a first coordinate value (for example, rᵢ) of the polar coordinate system may be dominant or a second coordinate value (for example, θᵢ) may be dominant by a process of rotating the wafer WF or a process of applying a chemical substance to the surface of the wafer WF. In this way, it is advantageous for an environment in which a factor indicating a specific coordinate is dominant to be reflected in calculating a distance value by a specific process.

In some embodiments, on the polar coordinate system, the processor 121 may calculate a first correction difference value based on a first difference value (for example, dr_{i,j}) between a first coordinate value (for example, rᵢ) of the target semiconductor chip TCHP and a first coordinate value (for example, rⱼ) of the peripheral semiconductor chip PCHP and a preset correction factor. In some embodiments, on the polar coordinate system, the processor 121 may calculate a second correction difference value based on a second difference value (for example, dθ_{i,j}) between a second coordinate value (for example, θᵢ) of the target semiconductor chip TCHP and a second coordinate value (for example, θⱼ) of the peripheral semiconductor chip PCHP and a correction factor. The first correction difference value dr′_{i,j} and the second correction difference value dθ′_{i,j} may be calculated according to Equation 4 below.

$${dr}_{i , j}^{′} = {s}_{1} d {r}_{i , j} , d {θ}_{i , j}^{′} = \frac{d {θ}_{i , j}}{{s}_{1}} , {s}_{1} > 0 \qquad Equation 4$$

Here, s₁ is a first correction coefficient and is greater than 0.

In some embodiments, the processor 121 may calculate a distance value based on the first correction difference value dr′_{i,j} and the second correction difference value dθ′_{i,j}. The distance value may be calculated according to Equation 3 described above. In some embodiments, when the first coordinate value (for example, rᵢ) of the polar coordinate system is dominant, the correction coefficient (for example, the first correction coefficient (s₁)) may increase. Accordingly, components of the first coordinate value (for example, rᵢ) may be more reflected in the distance value. In some embodiments, when the second coordinate value (for example, θᵢ) of the polar coordinate system is dominant, the correction coefficient (for example, the first correction coefficient (s₁)) may be reduced. Accordingly, the second coordinate value (for example, θᵢ) of the polar coordinate system may be more reflected in the distance value.

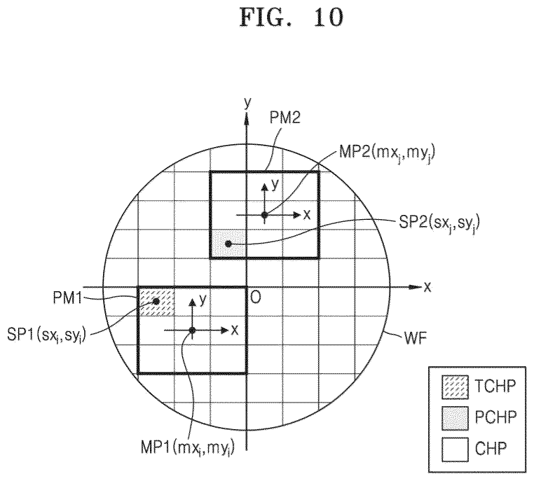

FIG. 10 is a diagram illustrating coordinates and distances in a photo shot coordinate system by way of example.

Referring to FIG. 10, the photo shot coordinate system may indicate a position of a photo shot in a photomask. In some embodiments, the origin O of the photo shot coordinate system may be a coordinate corresponding to the center of the wafer WF when the wafer WF is assumed to be a concentric circle on a coordinate plane. However, the origin is not limited thereto. In some embodiments, the origin O of the photo shot coordinate system may be a coordinate corresponding to the center of a certain semiconductor chip CHP. Coordinates in the photo shot coordinate system may include a central coordinate of a photomask and a position coordinate of a photo shot. In this case, the position coordinate of the photo shot may be a coordinate corresponding to the center of the semiconductor chip CHP when the central coordinate of each photomask is moved in parallel to the origin O. A relationship between the Cartesian coordinate system and the photo shot coordinate system is represented by Equation 5 below.

$$x = m x + s x , y = m y + s y \qquad Equation 5$$

Here, mx is a first center coordinate value of a photomask, my is a second central coordinate value of the photomask, sx is a first position coordinate value of a photo shot in the photomask, and sy is a second position coordinate value of the photo shot in the photomask.

The size of the photomask may correspond to the number of semiconductor chips CHP included in the photomask. For example, in some embodiments, nine semiconductor chips CHP may be included in one photomask. The size of the photomask may be determined in advance.

The target semiconductor chip TCHP may be included in a first photomask PM1. The peripheral semiconductor chip PCHP may be included in a second photomask PM2.

In some embodiments, a distance value dS_{i,j} between the target semiconductor chip TCHP and a certain peripheral semiconductor chip PCHP may be calculated according to Equation 6 below.

$$for i , j = 1 , 2 , ... , N ( = netdie ) \qquad Equation 6$$

$${dS}_{i , j} = \sqrt{{ds}_{i , j}^{2} + d {m}_{i , j}^{2}}$$

$$where$$

$$d {s}_{i , j} = \sqrt{{( s {x}_{i} - s {x}_{j} )}^{2} + {( s {y}_{i} - s {y}_{j} )}^{2}} , d {m}_{i , j} = \sqrt{{( m {x}_{i} - m {x}_{j} )}^{2} + {( m {y}_{i} - m {y}_{j} )}^{2}}$$

Here, dm_{i,j} denotes a first distance value between a position (for example, a first center coordinate MP1(mxᵢ,myᵢ)) of the first photomask PM1 corresponding to the target semiconductor chip TCHP and a position of the second photomask PM2 corresponding to a peripheral semiconductor chip (for example, a second center coordinate MP2(mxⱼ,myⱼ)) ds_{i,j} denotes a second distance value between a photo shot position (for example, a first position coordinate SP1(sxᵢ,syᵢ)) of the target semiconductor chip TCHP in the first photomask PM1 and a photo shot position (for example, a first position coordinate SP2(sxⱼ,syⱼ)) of the target semiconductor chip TCHP in the second photomask PM2.

In some embodiments, the type of dominant coordinates among the center coordinates and position coordinates of the photo shot coordinate system may be changed by a photomask process included in a wafer manufacturing process. In this way, it is advantageous for an environment in which a factor indicating a specific coordinate is dominant to be reflected in calculating a distance value by the photomask process.

In some embodiments, in the photo shot coordinate system, the processor 121 may calculate a first correction distance value based on a first distance value (for example, dm_{i,j}) and a correction coefficient. The correction coefficient may be preset. In some embodiments, in the photo shot coordinate system, the processor 121 may calculate a second correction distance value, based on a second distance value (for example, ds_{i,j}) and a correction coefficient. A first correction distance value dm′_{i,j} and a second correction distance value ds′_{i,j} may be calculated according to Equation 7 below.

$${ds}_{i , j}^{′} = {s}_{2} d {s}_{i , j} , d {{m}^{′}}_{i , j} = \frac{d {m}_{i , j}}{{s}_{2}} , {s}_{2} > 0 \qquad Equation 7$$

Here, s₂ denotes a second correction coefficient and is greater than zero.

In some embodiments, the processor 121 may calculate a distance value based on the first correction distance value dm′_{i,j} and the second correction distance value ds′_{i,j}. The distance value may be calculated according to Equation 6 described above. In some embodiments, when the first distance value (for example, dm_{i,j}) of the photo shot coordinate system is dominant, a correction coefficient (for example, the second correction coefficient s₂) may increase. In some embodiments, when the second distance value (for example, ds_{i,j}) of the photo shot coordinate system is dominant, the correction coefficient (for example, the second correction coefficient s₂) may be reduced.

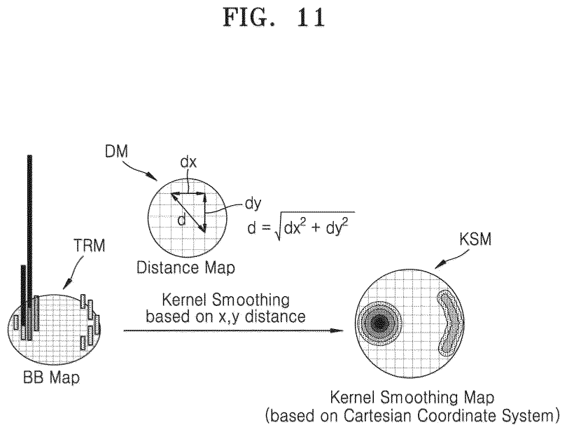

FIG. 11 is a diagram illustrating an example of generating a kernel smoothing map KSM, according to some embodiments.

Referring to FIG. 11, the semiconductor chip CHP may be implemented as a memory chip. A test result map TRM may be the defective count map CCM of FIG. 5 and may include a bad block (BB) map indicating the number of bad blocks included in the memory chip. The number of bad blocks included in each memory chip may be represented in the BB map by a bar shape in FIG. 11. However, the embodiments are not limited thereto, and the test result map TRM may include the bit map BM of FIG. 4.

The processor 121 may generate a two-dimensional distance map DM according to one of a plurality of two-dimensional coordinate systems. Referring to FIGS. 8 and 11, the processor 121 may generate, for example, a two-dimensional distance map DM according to the Cartesian coordinate system of FIG. 8.

The processor 121 may calculate a weighted average value corresponding to a potential failure risk value for each target semiconductor chip TCHP based on the test result map TRM and the two-dimensional distance map DM.

One weighted average value for each target semiconductor chip TCHP may be calculated according to Equation 8 below.

$$for i , j = 1 , 2 , ... , N ( = netdie ) , \qquad Equation 8$$

$$let {d}_{i} as {i}_{th} die on wafer ,$$

$${b}_{i} as its failure information ( 0 for pass , 1 for fail )$$

$$or a number of failed components ,$$

$$I ( {d}_{j} ) as its nonmissing indicator ( i . e . 0 if missing , else 1 )$$

$$S ( {d}_{i} ) = ( {\sum }_{j} \frac{I ( {d}_{j} ) {f}_{1} ( {b}_{j} )}{{f}_{2} ( {D}_{i , j} )} ) / ( {\sum }_{j} \frac{I ( {d}_{j} )}{{f}_{2} ( {D}_{i , j} )} )$$

Here, S(dᵢ) denotes a weighted average value. dᵢ denotes a target semiconductor chip (i is a positive integer). dⱼ denotes a peripheral semiconductor chip (j is a positive integer). bⱼ denotes a test result value. For example, in some embodiments, when the test result map TRM is a bit map BM, the test result value is failure information, that is, a single-bit value indicating whether a semiconductor chip passes or fails. In some embodiments, when the test result map TRM is a defective count map CCM, the test result value is an integer value indicating the number of failed components. D_{i,j} is a distance value of the two-dimensional distance map DM. The distance value of the two-dimensional distance map DM may be calculated according to Equation 1 described above with reference to FIG. 8. Equation 2 may be used to calculate the distance value of the two-dimensional distance map DM. I(dⱼ) is a single-bit value indicating whether the test result value is missing. f₁(bⱼ) is a first function that has a negative second derivative function and increases as bⱼ increases. f₂(D_{i,j}) is a second function that increases as D_{i,j} increases. Each of the first function f₁(bⱼ) and the second function f₂(D_{i,j}) may be referred to as a physical model. In some embodiments, a value of the first function is 0 (for example, f₁(0)=0), and the second function f₂(D_{i,j}) may have a value that is greater than 0.

When there are a plurality of target semiconductor chips TCHP, the weighted average values may be calculated according to Equation 8 described above. The processor 121 may generate a kernel smoothing map KSM including the weighted average values. Generating the kernel smoothing map KSM may be equivalent to an operation of calculating the weighted average values for the target semiconductor chips TCHP included in the wafer WF.

Although one two-dimensional coordinate system is assumed to be the Cartesian coordinate system in FIG. 11, the two-dimensional coordinate system is not limited thereto. One two-dimensional coordinate system may be a polar coordinate system, and the distance value of the two-dimensional distance map DM according to the polar coordinate system may be calculated according to Equation 3 (when necessary, Equation 4 is further used) described above with reference to FIG. 9. In some embodiments, one two-dimensional coordinate system may be a photo shot coordinate system, and the distance value of the two-dimensional distance map DM according to the photo shot coordinate system may be calculated according to Equation 6 (Equation 7 may be further used) described above with reference to FIG. 10.

FIG. 12 is a diagram illustrating an example of a test result map and a kernel smoothing map, according to some embodiments.

Referring to FIG. 12, when there is a semiconductor chip CHP that failed the test on a preceding test item among a plurality of test items, a test on a subsequent test item may not be performed. That is, a test result value of the corresponding semiconductor chip CHP for a subsequent test item may be a blank N/A. Accordingly, the test result map may include blanks N/A as illustrated in FIG. 12.

It is assumed that the first semiconductor chip CHP1 and the second semiconductor chip CHP2 are target semiconductor chips TCHP. A distribution form and the number of peripheral semiconductor chips PCHP having a test result value of 1 around the first semiconductor chip CHP1 may be the same as or very similar to a distribution form and the number of peripheral semiconductor chips PCHP having a test result value of 1 around the second semiconductor chip CHP2. For example, in the test result map, the number of peripheral semiconductor chips PCHP having a test result value of 1 in the vicinity of the first semiconductor chip CHP1 may be 12. In the test result map, the number of peripheral semiconductor chips PCHP having a test result value of 1 in the vicinity of the second semiconductor chip CHP2 may be 12. A distance value between the peripheral semiconductor chip PCHP having a test result value is 1 and the first semiconductor chip CHP1 may be 1, 2, 1.4, 2.2, or 2.8. A distance value between the peripheral semiconductor chip PCHP having a test result value is 1 and the second semiconductor chip CHP2 may be 1, 2, 1.4, 2.2, or 2.8.

Although the distribution forms of the peripheral semiconductor chips PCHP having a test result value of 1 are the same as or very similar to each other, the blanks N/A (or missing) in the test result map (TEST RESULT MAP) may be concentrated around the second semiconductor chip CHP2 rather than the first semiconductor chip CHP1.

The kernel smoothing map may include a weighted average value for each semiconductor chip CHP calculated according to Equation 8 described above. In the kernel smoothing map, the weighted average value of the second semiconductor chip CHP2 may be greater than the weighted average value of the first semiconductor chip CHP1.

As described above, by acquiring a weighted average value regardless of a position of the semiconductor chip CHP or a peripheral missing situation, the semiconductor chip CHP with potential failure risk may be accurately sorted.

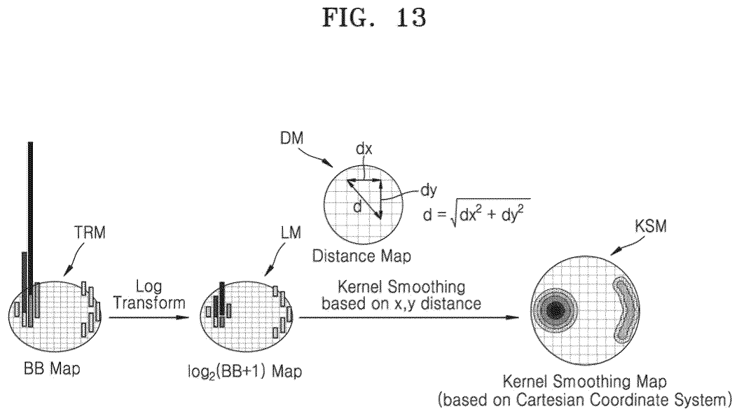

FIG. 13 is a diagram illustrating an example of generating a kernel smoothing map KSM, according to some embodiments.

Referring to FIG. 13, potential failure risk may be related to the number of failed components in the semiconductor chip CHP. In order to calculate a potential failure risk value according to an increase in the number of failed components in the semiconductor chip CHP, a log value obtained by summing a test result value and an offset value may be used to calculate the potential failure risk value instead of using the test result value as it is.

The processor 121 may convert the test result map TRM into a log map LM. The method of converting the test result map TRM into the log map LM is the same as described above with reference to FIG. 6. The base of log may be, for example, 2 with reference to FIG. 13 but embodiments are not limited thereto, and the base of log may be 10 according to some embodiments. In some embodiments, the test result value may be 0, and accordingly, an offset value may be included in a log value.

When the log map LM illustrated in FIG. 13 is generated, the first function f₁(bⱼ) of Equation 8 described above may be a log function illustrated in Equation 9 below.

$${f}_{1} ( {b}_{j} ) = {log}_{k} ( {b}_{j} + α ) \qquad Equation 9$$

Here, k denotes a positive number as a base of a log, and a denotes an offset value. For example, k may be 2 or 10 but embodiments are not limited thereto. For the sake of convenience of calculation, the offset value a may be 1. However, embodiments are not limited thereto.

The processor 121 may calculate a weighted average value corresponding to a potential failure risk value for each target semiconductor chip TCHP, based on the log map LM and the two-dimensional distance map DM (for example, a distance map according to the Cartesian coordinate system). The weighted average value corresponding to the potential failure risk value may be calculated according to Equation 8 described above. The processor 121 may generate the kernel smoothing map (KSM) including weighted average values.

In some embodiments, unlike the example illustrated in FIG. 13, the two-dimensional distance map DM may be a distance map based on a polar coordinate system or a distance map based on a photo shot coordinate system.

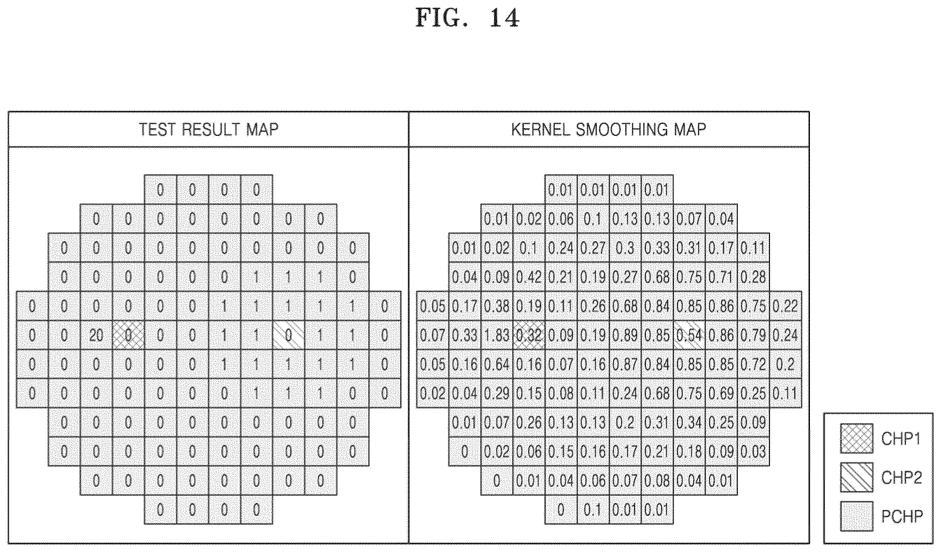

FIG. 14 is a diagram illustrating an example of a test result map and a kernel smoothing map, according to some embodiments.

Referring to FIG. 14, the first semiconductor chip CHP1 and the second semiconductor chip CHP2 are assumed to be target semiconductor chips TCHP. In the test result map, the number of peripheral semiconductor chips PCHP having a non-zero test result value (for example, an integer value indicating the number of failed components) in the vicinity of the first semiconductor chip CHP1 may be 1. The number of some peripheral semiconductor chips PCHP adjacent to the second semiconductor chip CHP2 and having a non-zero test result value may be 20.

As described above with reference to FIG. 13, the test result map may be converted into the log map LM. The kernel smoothing map of FIG. 14 may be generated based on the log map LM and a two-dimensional distance map. The number of peripheral semiconductor chips PCHP including failed components around the second semiconductor chip CHP2 is relatively greater than the number of peripheral semiconductor chips PCHP including failed components around the first semiconductor chip CHP1, and accordingly, a weighted average value of the second semiconductor chip CHP2 may be greater than a weighted average value of the first semiconductor chip CHP1 in the kernel smoothing map.

As described above, by using a log value to calculate a weighted average value, the semiconductor chip CHP with potential failure risk may be accurately sorted.

An influence of the peripheral semiconductor chip PCHP may be reduced exponentially according to a distance between the target semiconductor chip TCHP and the peripheral semiconductor chip PCHP. This exponential reduction is because similarity of a process environment (concentration of a chemical substance and so on) may be reduced exponentially according to a distance. Accordingly, the similarity of the process environment, which is reduced exponentially according to a distance, may be reflected in the second function f₂(D_{i,j}) of Equation 8 described above. A value of the second function f₂(D_{i,j}) may be referred to as a weighted value. In some embodiments, the second function f₂(D_{i,j}) may be an exponential function, such as a function of Equation 10 below.

$${f}_{2} ( {D}_{i , j} ) = {s}_{x}^{{D}_{i , j}} \qquad Equation 10$$

Here, sₓ denotes a preset exponent that is greater than 1. The index sₓ may correspond to the peripheral range PERIRGN including peripheral semiconductor chips. In this case, as the exponent sₓ increases, the peripheral range PERIRGN may be reduced. That is, as the index sₓ increases, the number of peripheral semiconductor chips PCHP included in the peripheral range PERIRGN may be reduced. Accordingly, semiconductor chips adjacent to the target semiconductor chip TCHP may be considered as the peripheral semiconductor chips PCHP. As the exponent sₓ is reduced, the peripheral range PERIRGN may increase. That is, as the index sₓ is reduced, the number of peripheral semiconductor chips PCHP included in the peripheral range PERIRGN may increase. Accordingly, semiconductor chips relatively far from the target semiconductor chip TCHP may be considered as the peripheral semiconductor chips PCHP.

As described above, by calculating a weighted average value by considering similarity of a process environment, which is reduced exponentially according to a distance, the semiconductor chip CHP with potential failure risk may be accurately sorted.

FIG. 15 is a diagram illustrating an example of generating a final kernel smoothing map FKSM, according to some embodiments.

Referring to FIG. 15, failure patterns that may be generated in various processes may be different from each other for each of test items and/or positions of the wafer WF and the semiconductor chips CHP. Accordingly, in order to sort semiconductor chips with potential failure risk in response to various failure patterns, it is advantageous for a specific weighted average value to be selected from among weighted average values according to distance maps in different two-dimensional coordinate systems.

The processor 121 may generate two-dimensional distance maps according to each of at least two two-dimensional coordinate systems among a Cartesian coordinate system, a polar coordinate system, and a photo shot coordinate system. Referring to FIG. 15, the processor 121 may generate, for example, a first distance map DM1 according to the Cartesian coordinate system and a second distance map DM2 according to the polar coordinate system.

The processor 121 may calculate a weighted average value for each two-dimensional distance map, based on distance values of each two-dimensional distance map and test result values of the test result map TRM. Referring to FIG. 15, the processor 121 may convert, for example, the test result map TRM into a log map LM. The processor 121 may calculate a first weighted average value according to the first distance map DM1 by substituting distance values of the first distance map DM1 and log values of the log map LM into Equation 8 described above. The processor 121 may calculate a second weighted average value according to the second distance map DM2 by substituting distance values of the second distance map DM1 and the log values of the log map LM into Equation 8 described above. In some embodiments, test result values of the test result map TRM may be directly used to calculate a weighted average value as in the example of FIG. 11.

The processor 121 may extract the greatest value among the first weighted average value and the second weighted average value as a potential failure risk value.

When there a plurality of target semiconductor chips TCHP, the first weighted average values and the second weighted average values may be calculated, and the processor 121 may generate a first kernel smoothing map KSM1 including the first weighted average values and a second kernel smoothing map KSM2 including the second weighted average values. The processor 121 may generate a final kernel smoothing map FKSM including die-wise maximum values for each die (or for each semiconductor chip CHP) by using the first kernel smoothing map KSM1 and the second kernel smoothing map KSM2.

According to the above description, there is an effect of accurately sorting a semiconductor chip with potential failure risk in response to various failure patterns.

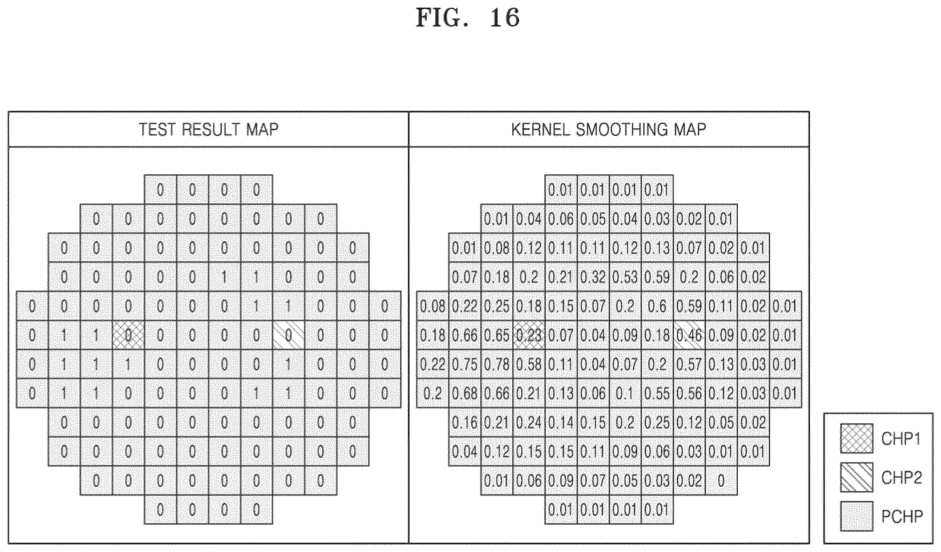

FIG. 16 is a diagram illustrating an example of a test result map and a kernel smoothing map, according to some embodiments.

Referring to FIG. 16, the first semiconductor chip CHP1 and the second semiconductor chip CHP2 are assumed to be target semiconductor chips TCHP. In the test result map, the number of peripheral semiconductor chips PCHP, which have a test result value of 1 for each distance based on the Cartesian coordinate system, around the first semiconductor chip CHP1 may be equal to the number of peripheral semiconductor chips PCHP, which have a test result value of 1 for each distance based on the Cartesian coordinate system, around the second semiconductor chip CHP2. For example, when the distance value based on the Cartesian coordinate system is 1 or 2.2, the number of peripheral semiconductor chips PCHP having a test result value of 1 may be 2. When the distance value based on the Cartesian coordinate system is 1.4, 2, or 2.8, the number of peripheral semiconductor chips PCHP having a test result value of 1 may be 1. When the distance value based on the Cartesian coordinate system is 2, the number of peripheral semiconductor chips PCHP having a test result value of 1 may be 1. Accordingly, a weighted average value of in the first semiconductor chip CHP1 based on the Cartesian coordinate system may be similar to a weighted average value of the second semiconductor chip CHP2 based on the Cartesian coordinate system.

Although the number of peripheral semiconductor chips PCHP, which have a test result value of 1 for each distance based on the Cartesian coordinate system, around the first semiconductor chip CHP1 may be equal to the number of peripheral semiconductor chips PCHP, which have a test result value of 1 for each distance based on the Cartesian coordinate system, around the second semiconductor chip CHP2, but a distribution form of the peripheral semiconductor chips PCHP having a test result value of 1 around the first semiconductor chip CHP1 may be different from a distribution form of the peripheral semiconductor chips PCHP having a test result value of 1 around the second semiconductor chip CHP2. For example, most of the peripheral semiconductor chips PCHP having a test result value of 1 may be concentrated in the vicinity of the first semiconductor chip CHP1. The peripheral semiconductor chips PCHP having a test result value of 1 may be scattered in the vicinity of the second semiconductor chip CHP2. That is, the distribution form of the peripheral semiconductor chips PCHP having a test result value of 1 in the vicinity of the second semiconductor chip CHP2 may be similar to an arc shape. Accordingly, a weighted average value of the first semiconductor chip CHP1 based on a polar coordinate system may be different from a weighted average value of the second semiconductor chip CHP2 based on the polar coordinate system.

The kernel smoothing map of FIG. 16 may be the final kernel smoothing map FKSM. In the kernel smoothing map, the weighted average value of the second semiconductor chip CHP2 may be greater than the weighted average value of the first semiconductor chip CHP1.

As described above, the semiconductor chips CHP with potential failure risk may be accurately sorted by calculating the weighted average value by considering the distribution form of the peripheral semiconductor chips PCHP.

FIG. 17 is a diagram illustrating an example of generating the final kernel smoothing map FKSM, according to some embodiments.

Referring to FIG. 17, a failure pattern may be generated in various processes as described above with reference to FIG. 15. Like a diffusion process, there is a process in which a chemical substance acts in a horizontal direction of a wafer plane in the Cartesian coordinate system. In some embodiments, there is a process in which the wafer WF is rotated in a polar coordinate system, such as a CMP process and a PR development process, or there is a process in which a chemical substance acts in a direction perpendicular to a plane of the wafer WF in the polar coordinate system, such as an etch process. There is a photomask process in ae photo shot coordinate system. It is advantageous to sort a semiconductor chip with potential failure risk in response to failure patterns that are generated in various processes.

The processor 121 may generate two-dimensional distance maps according to each of the Cartesian coordinate system, the polar coordinate system, and the photo shot coordinate system. Specifically, the processor 121 may generate the first distance map DM1 based on the Cartesian coordinate system, the second distance map DM2 based on the polar coordinate system, and a third distance map DM3 based on the photo shot coordinate system.

The processor 121 may calculate a weighted average value for each two-dimensional distance map based on distance values of each two-dimensional distance map and test result values of the test result map TRM. As described above with reference to FIG. 15, the processor 121 may calculate the first weighted average value according to the first distance map DM1 and the second weighted average value according to the second distance map DM2. The processor 121 may calculate a third weighted average value according to the third distance map DM3 by substituting distance values of the third distance map DM3 and log values of the log map LM into Equation 8. In some embodiments, the test result values of the test result map TRM may be directly used to calculate a weighted average value.

The processor 121 may extract the greatest value among the first to third weighted average values as a potential failure risk value. When there are a plurality of target semiconductor chips TCHP, the processor 121 may generate the first kernel smoothing map KSM1, the second kernel smoothing map KSM2, and a third kernel smoothing map KSM3. The processor 121 may generate the final kernel smoothing map FKSM by using the first to third kernel smoothing maps KSM1, KSM2, and KSM3.

According to the above description, there is an effect of accurately sorting a semiconductor chip with potential failure risk in response to various failure patterns.

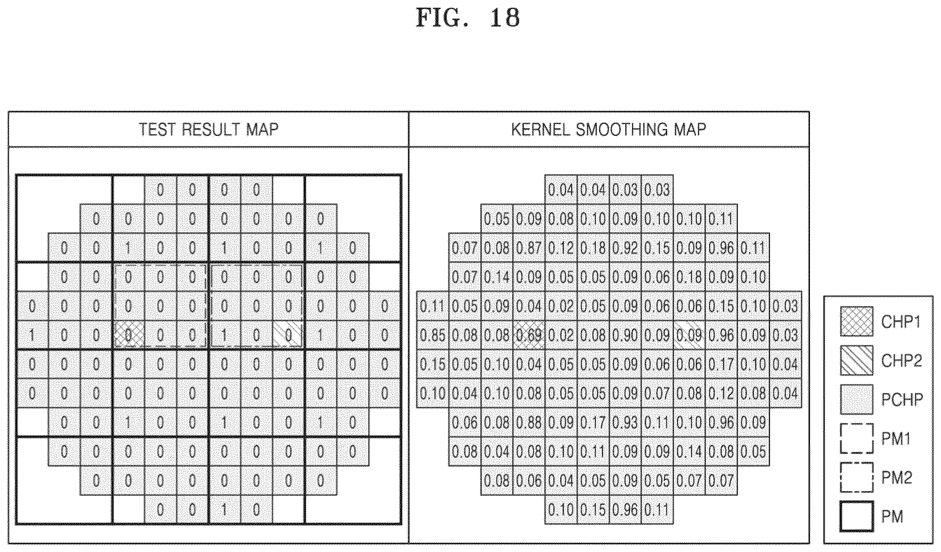

FIG. 18 is a diagram illustrating an example of a test result map and a kernel smoothing map, according to some embodiments.

Referring to FIG. 18, photomasks PM may be arranged as illustrated in FIG. 18 by using some (for example, nine) of a plurality of semiconductor chips as a unit. In some embodiments, a photomask process may be performed, and then the peripheral semiconductor chip PCHP in the third row and the first column in one photomask PM may fail the test. That is, test result values of the peripheral semiconductor chips PCHP located in the third row and the first column in some of the photomasks PM may be 1 in common.

The first semiconductor chip CHP1 and the second semiconductor chip CHP2 are assumed to be target semiconductor chips TCHP. The first semiconductor chip CHP1 and the second semiconductor chip CHP2 may be included in different photomasks. For example, the first semiconductor chip CHP1 may be located in the third row and the first column in the first photomask PM1. The second semiconductor chip CHP2 may be located in the third row and the third column in the second photomask PM2. A test result value of the peripheral semiconductor chip PCHP located in the third row and the first column in the second photomask PM2 may be 1.

The number of peripheral semiconductor chips PCHP, which have a test result value of 1 for each distance based on a Cartesian coordinate system, around the first semiconductor chip CHP1 may be similar to the number of peripheral semiconductor chips PCHP, which have a test result value of 1 for each distance based on a polar coordinate system, around the second semiconductor chip CHP2. Accordingly, a weighted average value based on the Cartesian coordinate system may be similar to a weighted average value based on the polar coordinate system.

However, the peripheral semiconductor chip PCHP having a test result value of 1 in the third row and the first column in the peripheral photomask PM is distributed for each of the photomasks PM, and the first semiconductor chip CHP1 is equally located in the third row and the first column in the first photomask PM1, and accordingly, a weighted average value of the first semiconductor chip CHP1 based on the photo coordinate system may be greater than a weighted average value of the second semiconductor chip CHP2.

The kernel smoothing map of FIG. 18 may be the final kernel smoothing map FKSM of FIG. 17. In the kernel smoothing map, a weighted average value of the first semiconductor chip CHP1 may be greater than a weighted average value of the second semiconductor chip CHP2.

As described above, a semiconductor chip CHP with potential failure risk may be accurately sorted by calculating a weighted average value by considering a distribution form of the peripheral semiconductor chip PCHP included in the photomask.

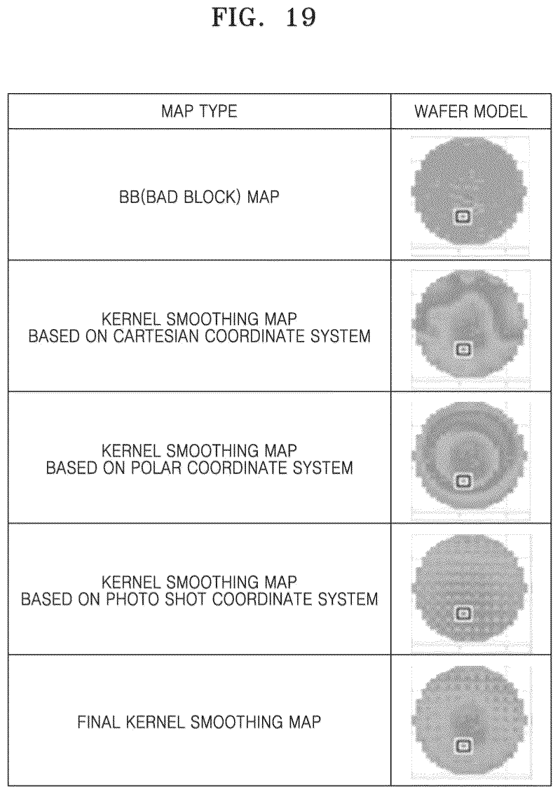

FIG. 19 illustrates an example of wafer models for each map type, according to some embodiments.

Referring to FIG. 19, the wafer models may indicate distributions of values generated based on the test result map TRM.

A wafer model according to a bad block (BB) map may indicate a distribution of integer values of the defective count map CCM when the test result map TRM is the defective count map CCM including the number of bad blocks.

A wafer model according to a Cartesian coordinate system-based kernel smoothing map may indicate a distribution of potential failure risk values based on a Cartesian coordinate system.

A wafer model according a polar coordinate system-based kernel smoothing map may indicate a distribution of potential failure risk values based on a polar coordinate system.

A wafer model according to a photo shot coordinate system-based kernel smoothing map may indicate a distribution of potential failure risk values based on a photo shot coordinate system.

A wafer model according to a final kernel smoothing map may indicate a distribution of greatest values extracted for each die in two or more kernel smoothing maps.

A wafer model according to a coordinate system-based kernel smoothing map may better cover defective positions than the wafer model according to the BB map. A wafer model according to a final kernel smoothing map may best cover positions of failed chips.

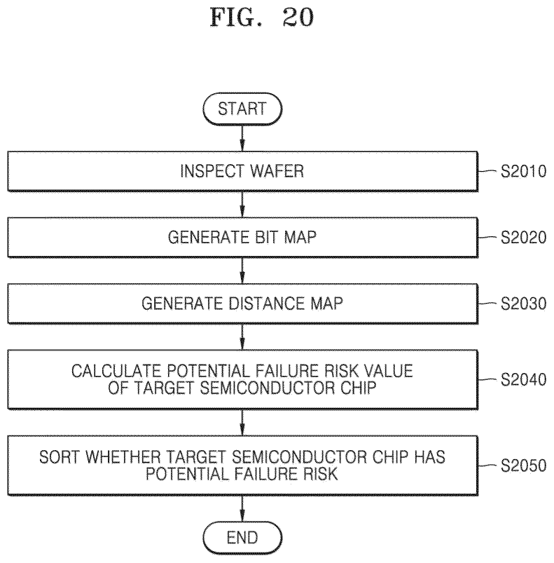

FIG. 20 is a flowchart illustrating a method according to some embodiments.

Referring to FIGS. 1 and 20, the method of FIG. 20 may be performed by the device 120 of FIG. 1. The method of FIG. 20 may include operation S2010, operation S2020, operation S2030, operation S2040, and operation S2050.

In operation S2010, the processor 121 may inspect the wafer WF by performing a wafer test according to each of a plurality of test items. Specifically, for example, the processor 121 may receive measurement data MSNT DATA obtained by measuring the semiconductor chip CHP by using the measurement device 110 and may sequentially test a plurality of test items based on the measurement data MSNT DATA for each semiconductor chip CHP. When test of all semiconductor chips included in the wafer WF is completed, the processor 121 may generate an inspection result of the wafer WF.

In operation S2020, the processor 121 may generate a bit map based on the inspection result of the wafer WF. The bit map may include bit values of the plurality of semiconductor chips. The bit value may indicate whether the plurality of semiconductor chips fail at least one test item among a plurality of test items. The bit map may be the same as the bit map BM described above with reference to FIG. 4.

In some embodiments, in operation S2020, the processor 121 may generate a first bit map and/or a second bit map. The first bit map and the second bit map may each include a single-bit value. The single-bit value of the first bit map may indicate whether the plurality of semiconductor chips fail one test item selected from among a plurality of test items. The single-bit value of the second bit map may indicate whether the plurality of semiconductor chips fail all of the plurality of test items. When a test result of a test item indicates a test pass, the single-bit value may be zero. When the test result of the test item indicates a test failure, the single-bit value may be 1.

In operation S2030, the processor 121 may generate a distance map. For example, the processor 121 may generate the distance map by using an inspection result of the wafer WF, a test result map, and/or coordinate system data. One or more distance maps may be generated. The distance map may include distance values in one coordinate system. The distance value may indicate a distance between a target semiconductor chip and a peripheral semiconductor chip. The target semiconductor chip, the peripheral semiconductor chip, and the distance map may be the same as those described above with reference to FIG. 7. An example of calculating a distance value in a coordinate system may be the same as described above with reference to FIGS. 8 to 10.

In operation S2040, the processor 121 may calculate a potential failure risk value of a target semiconductor chip. For example, the processor 121 may calculate the potential failure risk value of the target semiconductor chip based on the bit map and the distance map.

A potential failure risk value may be calculated according to Equation 8 described above. In this case, bⱼ of Equation 8 described above is a bit value, and I(dⱼ) is a single-bit value indicating whether the bit value is missing.

The first function f₁(bⱼ) of Equation 8 described above may be a log function according to Equation 9 described above.

The second function f₂(D_{i,j}) of Equation 8 described above may be an exponential function according to the Equation 10 described above. As the index sₓ increases, the number of peripheral semiconductor chips may be reduced. As the exponent sₓ is reduced, the number of peripheral semiconductor chips may increase.

In operation S2050, the processor 121 may sort whether the target semiconductor chip is a semiconductor chip with potential failure risk, based on the potential failure risk value. Operation S2050 may be the same as operation S350 of FIG. 3.

As described above, by sorting a potential failure semiconductor chip, an effect of reducing costs to be consumed in a subsequent process and various failed products to be provided to customers may be obtained.

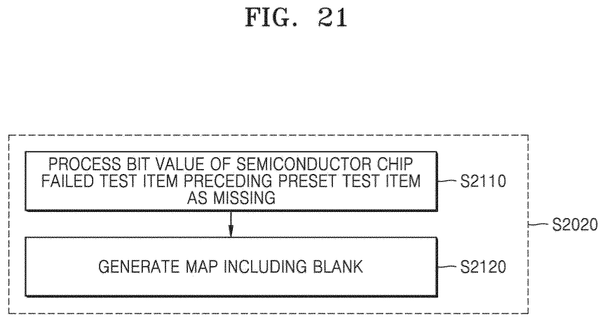

FIG. 21 is a flowchart illustrating an example of operation S2020 of FIG. 20, according to some embodiments.

Referring to FIGS. 1 and 21, operation S2020 of FIG. 20 may include operation S2110 and operation S2120.

In operation S2110, the processor 121 may process, as missing, a bit value of a semiconductor chip that failed the test item preceding the specific test item. Here, the specific test item may be at least one test item among a plurality of test items.

In operation S2120, the processor 121 may generate a map including a blank (for example, N/A) in which the bit value of the failed semiconductor chip is missing. Here, the map may be similar to the test result map described above with reference to FIG. 12.

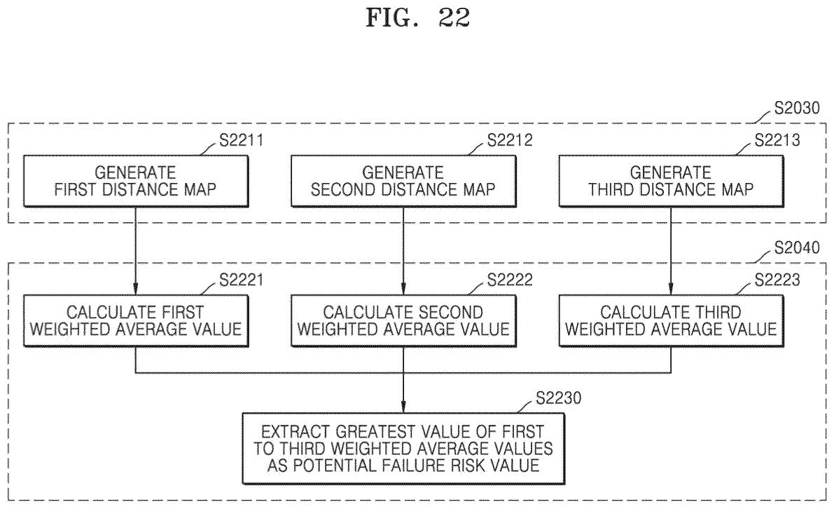

FIG. 22 is a flowchart illustrating an example of operation S2030 and operation S2040 of FIG. 20, according to some embodiments.

Referring to FIGS. 1 and 22, operation S2030 of FIG. 20 may include operation S2211, operation S2212, and operation S2213.

In operation S2211, the processor 121 may generate a first distance map according to a Cartesian coordinate system. Operation S2211 is the same as described above with reference to FIG. 8. In operation S2212, the processor 121 may generate a second distance map according to a polar coordinate system. Operation S2212 is the same as described above with reference to FIG. 9. In operation S2213, the processor 121 may generate a third distance map according to a photo shot coordinate system. Operation S2213 is the same as described above with reference to FIG. 10.

Operation S2040 of FIG. 20 may include operation S2221, operation S2222, operation S2223, and operation S2230.

In operation S2221, the processor 121 may calculate a first weighted average value based on distance values of the first distance map and bit values of the bit map. In operation S2222, the processor 121 may calculate a second weighted average value based on distance values of the second distance map and the bit values of the bit map. In operation S2223, the processor 121 may calculate a third weighted average value based on distance values of the third distance map and the bit values of the bit map. The first to third weighted average values are the same as described above with reference to FIGS. 11 and 17.

In operation S2230, the processor 121 may extract the greatest value among the first to third weighted average values as a potential failure risk value. Operation S2230 is the same as described above with reference to FIG. 17.

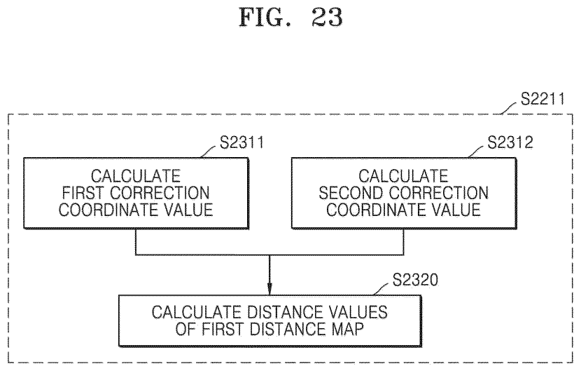

FIG. 23 is a flowchart illustrating an example of operation S2211 of FIG. 22, according to some embodiments.

Referring to FIGS. 1 and 23, operation S2211 of FIG. 22 may include operation S2311, operation S2312, and operation S2320.

In operation S2311, the processor 121 may calculate a first correction coordinate value. In operation S2312, the processor 121 may calculate a second correction coordinate value. The first correction coordinate value and the second correction coordinate value may be calculated according to Equation 2 described above.

In operation S2320, the processor 121 may calculate a distance value of the first distance map based on the first and second correction coordinate values. The distance value of the first distance map may be calculated according to a combination of Equation 1 and Equation 2 described above.

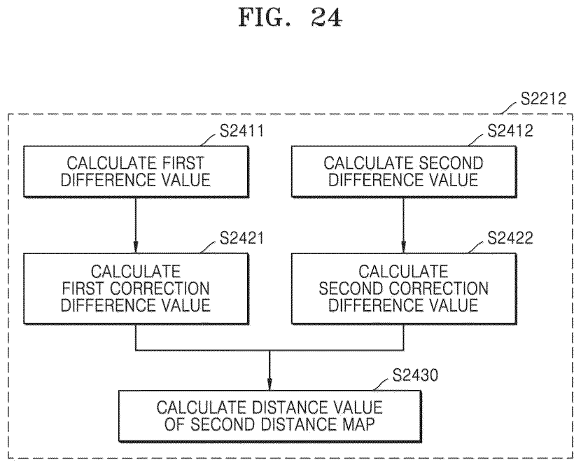

FIG. 24 is a flowchart illustrating an example of operation S2212 of FIG. 22, according to some embodiments.

Referring to FIGS. 1 and 24, operation S2212 of FIG. 22 may include operation S2411, operation S2412, operation S2421, operation S2422, and operation S2430.

In operation S2411, the processor 121 may calculate a first difference value between a first coordinate value of a target semiconductor chip and a first coordinate value of a peripheral semiconductor chip. In operation S2412, the processor 121 may calculate a second difference value between a second coordinate value of the target semiconductor chip and a second coordinate values of the peripheral semiconductor chip. The first difference value and the second difference value are respectively dr_{i,j} and dθ_{i,j} included in Equation 3 described above.

In operation S2421, the processor 121 may calculate a first correction difference value based on the first difference value and a correction coefficient. The correction coefficient may be preset. In operation S2422, the processor 121 may calculate a second correction difference value based on the second difference value and the correction coefficient. The first correction difference value and the second correction difference value may be calculated according to Equation 4 described above.

In operation S2430, the processor 121 may calculate a distance value of the second distance map based on the first correction difference value and the second correction difference value. The distance value of the second distance map may be calculated according to a combination of Equation 3 and Equation 4 described above.

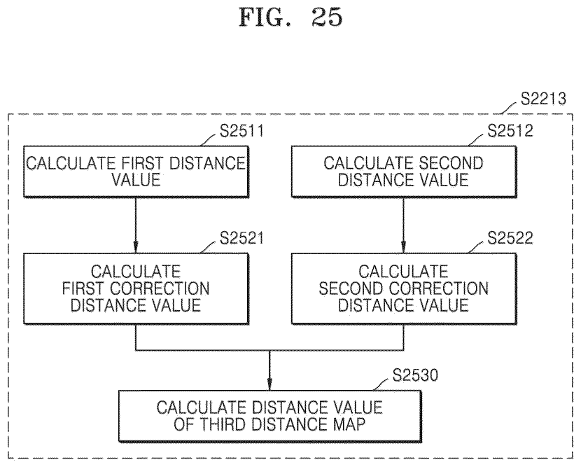

FIG. 25 is a flowchart illustrating an example of operation S2213 of FIG. 22, according to some embodiments.

Referring to FIGS. 1 and 25, operation S2213 of FIG. 22 may include operation S2511, operation S2512, operation S2521, operation S2522, and operation S2530.

In operation S2511, the processor 121 may calculate a first distance value between a position of a first photomask corresponding to a target semiconductor chip and a position of a second photomask corresponding to a peripheral semiconductor chip. In operation S2512, the processor 121 may calculate a second distance value between a photo shot position of the target semiconductor chip in a first photomask and a photo shot position of the target semiconductor chip in a second photomask. The first distance value and the second distance value are respectively dm_{i,j} and ds_{i,j} included in Equation 6 described above.

In operation S2521, the processor 121 may calculate a first correction distance value based on the first distance value and a preset correction coefficient. In operation S2522, the processor 121 may calculate a second correction distance value based on the second distance value and the correction coefficient. The first correction distance value and the second correction distance value may be calculated according to Equation 7 described above.

In operation S2530, the processor 121 may calculate a distance value of a third distance map based on the first correction distance value and the second correction distance value. The distance value of the third distance map may be calculated according to a combination of Equation 6 and Equation 7 described above.

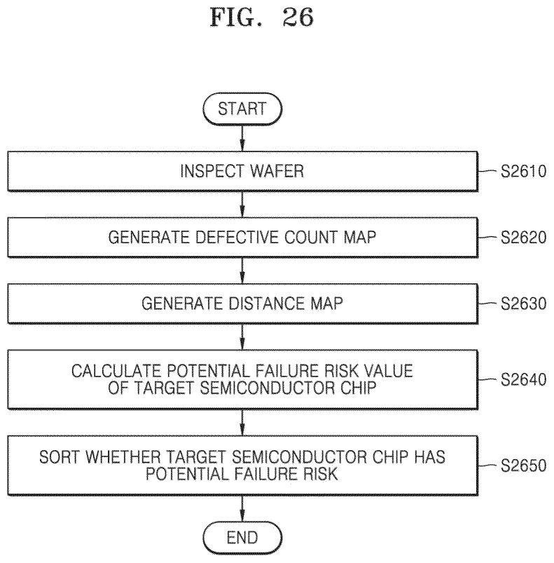

FIG. 26 is a flowchart illustrating a method according to some embodiments.

Referring to FIGS. 1 and 26, the method of FIG. 26 may be performed by the device 120 of FIG. 1. The method of FIG. 26 may include operation S2610, operation S2620, operation S2630, operation S2640, and operation S2650. Operation S2610 is the same as operation S2010 of FIG. 20, operation S2630 is the same as operation S2030 of FIG. 20, and operation S2650 is the same as operation S2050 of FIG. 20, and thus repeated descriptions thereof are omitted for conciseness.

In operation S2620, the processor 121 may generate a defective count map based on an inspection result of the wafer WF. The defective count map may include integer values of a plurality of semiconductor chips. The integer values may indicate the number of failed components included in the semiconductor chip that failed at least one test item among a plurality of test items. The defective count map may be the same as described above with reference to FIG. 5.

In some embodiments, in operation S2620, the processor 121 may generate a first defective count map and/or a second defective count map. The first defective count map and the second defective count map may each include integer values. An integer value of the first defective count map may indicate the number of components failed a test item selected from among a plurality of test items. A single-bit value of the second bit map may indicate the number of components failed all of the plurality of test items.

As described with respect to FIG. 21, operation S2620 may include operation of processing an integer value of a semiconductor chip that failed a test item preceding a specific test item as missing, and operation of generating a map including a blank (N/A) in which the integer value of the failed semiconductor chip is missing.

In operation S2640, the processor 121 may calculate a potential failure risk value of the target semiconductor chip based on the defective count map and the distance map.

The potential failure risk value according to the embodiment may be calculated according to Equation 8 described above. In this case, bⱼ of Equation 8 is an integer value, and I(dⱼ) is a single-bit value indicating whether the integer value is missing. The index sₓ and the number of peripheral semiconductor chip may be in inverse proportion to each other.

As described above, by sorting a potential failure chip, an effect of reducing costs to be consumed in a subsequent process and various failed products to be provided to customers may be obtained.

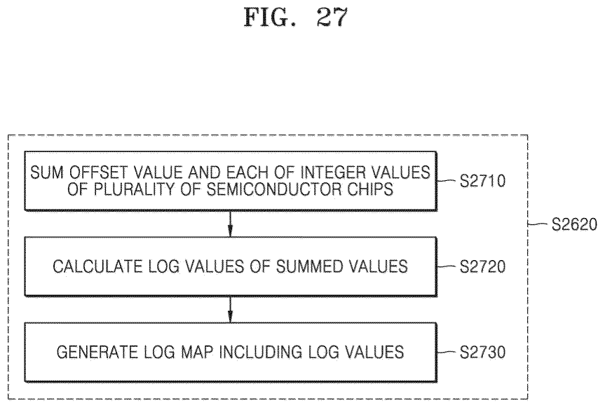

FIG. 27 is a flowchart illustrating an example of operation S2620 of FIG. 26, according to some embodiments.

Referring to FIGS. 1 and 27, operation S2620 of FIG. 26 may include operation

S2710, operation S2720, and operation S2730.

In operation S2710, the processor 121 may sum an offset value and integer values of a plurality of semiconductor chips.

In operation S2720, the processor 121 may calculate log values for the summed values.

In operation S2730, the processor 121 may generate a log map including the log values as a defective count map. The log map may be the same as described above with reference to FIG. 13.

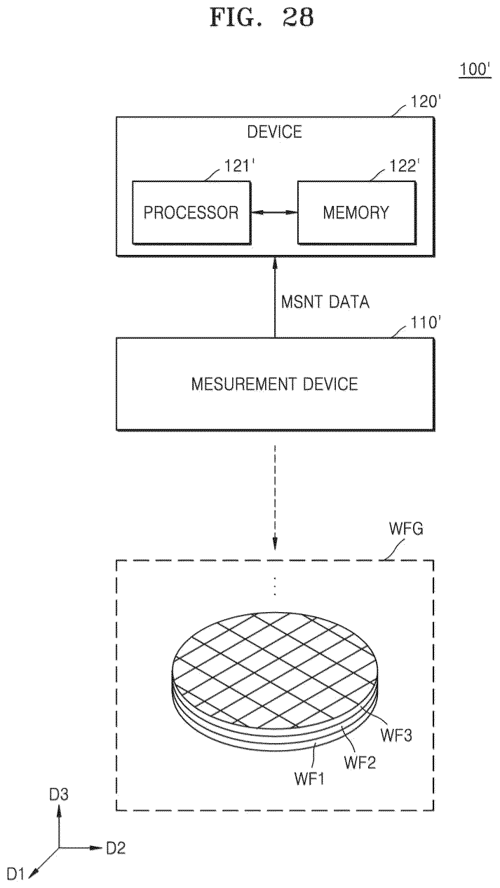

FIG. 28 is a diagram illustrating a system 100′ according to some embodiments.

Referring to FIG. 28, the system 100′ may sort failed chips from a wafer group WFG of which inspection is completed.

The wafer group WFG may include a plurality of wafers. For example, the wafer group WFG may include a first wafer WF1, a second wafer WF2, and a third wafer WF3 which are sequentially stacked. The first, second, and third wafers WF1, WF2, and WF3 may each include a plurality of semiconductor chips arranged in the first direction D1 and the second direction D2. The first, second, and third wafers WF1, WF2, and WF3 may be stacked in a third direction D3. The first, second, and third wafers WF1, WF2, and WF3 may be adjacent to each other. Semiconductor chips adjacent to a target semiconductor chip in the wafer group WFG may include semiconductor chips included in the same wafer and semiconductor chips included in adjacent wafers. The wafer group WFG including a preset number (for example, 25) of wafers may be referred to as a “lot”.

The system 100′ may include a measurement device 110′ and a device 120′.

The measurement device 110′ may actually measure the wafer group WFG. Specifically, for example, the measurement device 110′ may sequentially measure the first, second, and third wafers WF1, WF2, and WF3. The measurement device 110′ may output measurement data MSNT DATA for each wafer.

The device 120′ may inspect the wafer group WFG by using the measurement data MSNT DATA. The device 120′ may include a processor 121′ and a memory 122′.

The processor 121′ may execute instructions stored in the memory 122′. In some embodiments, the instructions may be provided to perform a method of sorting semiconductor chips with potential failure risk from the wafer group WFG.

The processor 121′ may acquire a test result map from an inspection result of the wafer group WFG. The test result map may include test result values of a plurality of semiconductor chips included in each wafer for each wafer.

The processor 121′ may generate a distance map including distance values between a target semiconductor chip and peripheral semiconductor chips. The target semiconductor chip may be a semiconductor device determined to pass as an inspection result among a plurality of semiconductor chips. One distance map may include distance values between a target semiconductor chip and peripheral semiconductor chips included in the wafer in which the target semiconductor chip is formed, in one three-dimensional coordinate system. One distance map may further include distance values between a target semiconductor chip and peripheral semiconductor chips included in a peripheral wafer in one three-dimensional coordinate system.

The processor 121′ may calculate a potential failure risk value of s target semiconductor chip based on the test result map and the distance map.

In some embodiments, the processor 121′ may convert the test result map into a log map. Specifically, the processor 121′ may sum an offset value and test result values of the test result map. The processor 121′ may calculate log values for the summed values. The processor 121′ may generate a log map including the log values. The processor 121′ may calculate a potential failure risk value based on the log map and the distance map.

The processor 121′ may sort whether a target semiconductor chip has potential failure risk based on the potential failure risk value.

The memory 122′ may include instructions for performing a method of testing a plurality of semiconductor chips according to a plurality of test items. The memory 122′ may store instructions for performing a method of sorting semiconductor chips with potential failure risk from the wafer group WFG of which inspection is completed. The memory 122′ may store coordinate system data for calculating positions of the wafer WF and/or the semiconductor chips CHP.

As described above, by sorting potential failure semiconductor chips from an inspection result of the wafer group WFG, an effect of reducing costs to be consumed in a subsequent process and various failed products to be provided to customers may be obtained.

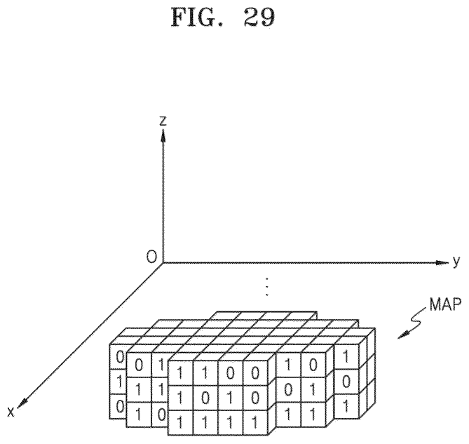

FIG. 29 is a diagram illustrating an example of a map in a three-dimensional coordinate system, according to some embodiments.

Referring to FIG. 29, in some embodiments, the three-dimensional coordinate system may be an orthogonal coordinate system, a cylindrical coordinate system, or a spherical coordinate system. FIG. 29 illustrates an example in which the three-dimensional coordinate system is the orthogonal coordinate system.

The map MAP may correspond to a test result map. The test result map may include a plurality of test result values of each wafer. Referring to FIGS. 28 and 29, for example, the test result map may include test result values of the first wafer WF1, test result values of the second wafer WF2, and test result values of the third wafer WF3. A wafer number or a wafer identifier may correspond to a coordinate value of the z axis in the three-dimensional coordinate system of FIG. 29. Test result values included in one wafer may correspond to values located on x-axis and y-axis planes in the three-dimensional coordinate system of FIG. 29.

In some embodiments, the processor 121′ may acquire any one of a first bit map, a second bit map, and a defective count map as a test result map. The first bit map may include single-bit values per wafer. A single-bit value of the first bit map may indicate whether one semiconductor chip included in each wafer passes or fails the test. The second bit map may include single-bit values per wafer. A single-bit value of the second bit map may indicate whether a component included in each semiconductor chip passes or fails the test. The defective count map may include integer values for each wafer. An integer value of the defective count map may indicate the number of failed components included in each semiconductor chip.

In some embodiments, the processor 121′ may calculate distance values based on first coordinate values, second coordinate values, and third coordinate values indicating positions of semiconductor chips included in the wafer group WFG on at least one three-dimensional coordinate system among various types of three-dimensional coordinate systems. For example, the first coordinate value may be an x-axis coordinate value, the second coordinate value may be a y-axis coordinate value, and the third coordinate value may be a z-axis coordinate value.

In some embodiments, the processor 121′ may generate a three-dimensional distance map according to any one of an orthogonal coordinate system, a cylindrical coordinate system, and a spherical coordinate system. The processor 121′ may calculate a weighted average value corresponding to a potential failure risk value based on distance values of a three-dimensional distance map and test result values of a test result map.

In some embodiments, the processor 121′ may generate three-dimensional distance maps according respectively to each of at least two three-dimensional coordinate systems among an orthogonal coordinate system, a cylindrical coordinate system, and a spherical coordinate system. The processor 121′ may calculate a weighted average value for each three-dimensional distance map based on the distance values of each three-dimensional distance map and the test result values of the test result map. The processor 121′ may extract the greatest value among weighted average values as a potential failure risk value.

The disclosed embodiments may be implemented in the form of a recording medium storing instructions executable by a computer. The instructions may be stored in the form of program code, and when executed by a processor, the instructions may generate program modules to perform operations of the disclosed embodiments. The recording medium may be implemented as a computer-readable recording medium.

The computer-readable recording medium may include all types of recording media in which instructions that may be decoded by a computer are stored. The computer-readable recording medium may include, for example, read only memory (ROM), random access memory (RAM), a magnetic tape, a magnetic disk, flash memory, an optical data storage device, and so on.

It is obvious to those skilled in the art that various embodiments herein may be modified or changed in various ways without departing from the scope or idea of the present disclosure. In view of the foregoing, when modifications and changes of various embodiments are within the scope of the following claims and equivalents, the such embodiments are considered to include the modifications and changes.

While various embodiments have been particularly shown and described with reference to the drawings, it will be understood that various changes in form and details may be made therein without departing from the spirit and scope of the following claims.

1. A device comprising:
a memory storing instructions for performing a method of sorting semiconductor chips with potential failure risk from a wafer of which inspection is completed; and
a processor configured to execute the instructions to cause the processor to at least:
acquire a test result map including test result values for each semiconductor chip of a plurality of semiconductor chips included in the wafer from an inspection result of the wafer,
generate a distance map including a distance value between a target semiconductor chip determined as an inspection pass among the plurality of semiconductor chips and one or more peripheral semiconductor chips of the target semiconductor chip in at least one coordinate system,
calculate a potential failure risk value of the target semiconductor chip based on the test result map and the distance map, and
determine whether the target semiconductor chip has the potential failure risk based on the potential failure risk value.

2. The device of claim 1, wherein the processor acquires any one map, as the test result map, among:
a first bit map including single-bit values indicating a test pass or a test failure of each semiconductor chip included in the wafer,
a second bit map including single-bit values indicating a test pass or a test failure of each of components included in each semiconductor chip included in the wafer, and
a defective count map including integer values indicating a number of failed components included in each semiconductor chip included in the wafer.

3. The device of claim 1, wherein the processor further executes the instructions to cause the processor to:
add an offset value to each of the test result values of the test result map to generate summed values,
calculate log values of the summed values,
generate a log map including the log values, and
calculate the potential failure risk value based on the log map and the distance map.

4. The device of claim 1, wherein the processor further executes the instructions to cause the processor to calculate the distance value for each of the one or more peripheral semiconductor chips based on first coordinate values and second coordinate values indicating positions of the plurality of semiconductor chips in at least one two-dimensional coordinate system among a Cartesian coordinate system, a polar coordinate system, and a photo shot coordinate system indicating a position of a photo shot in a photomask.

5. The device of claim 4, wherein the processor further executes the instructions to cause the processor to:
calculate a first correction coordinate value based on a ratio of a first coordinate value to a first integer value indicating a greatest number of semiconductor chips arranged in the wafer in a first direction,
calculate a second correction coordinate value based on a ratio of a second coordinate value to a second integer value indicating a greatest number of semiconductor chips arranged in the wafer in a second direction perpendicular to the first direction, and
calculate the distance value based on the first correction coordinate value and the second correction coordinate value.

6. The device of claim 4, wherein the processor further executes the instructions to cause the processor to:
calculate a first correction difference value based on a first difference value between a first coordinate value of the target semiconductor chip and a first coordinate value of the peripheral semiconductor chip and based on a correction coefficient in the polar coordinate system,
calculate a second correction difference value based on a second difference value between a second coordinate value of the target semiconductor chip and a second coordinate value of the peripheral semiconductor chip and based on the correction coefficient in the polar coordinate system, and
calculate the distance value based on the first correction difference value and the second correction difference value.

7. The device of claim 4, wherein the processor further executes the instructions to cause the processor to:
calculate a first correction distance value based on a first distance value between a position of a first photomask corresponding to the target semiconductor chip and a position of a second photomask corresponding to the peripheral semiconductor chip and based on a correction coefficient in the photo shot coordinate system,
calculate a second correction distance value based on a second distance value between a photo shot position of the target semiconductor chip in the first photomask and a photo shot position of the peripheral semiconductor chip in the second photomask and based on the correction coefficient in the photo shot coordinate system, and
calculate the distance value based on the first correction distance value and the second correction distance value.

8. The device of claim 1, wherein the processor further executes the instructions to cause the processor to:
generate a two-dimensional distance map according to any one of a Cartesian coordinate system, a polar coordinate system, and a photo shot coordinate system indicating a position of a photo shot in a photomask, and
calculate a weighted average value corresponding to the potential failure risk value based on distance values of the two-dimensional distance map and test result values of the test result map.

9. The device of claim 8, wherein the weighted average value is calculated by Equation 1 below,
$$S ( {d}_{i} ) = ( {\sum }_{j} \frac{I ( {d}_{j} ) {f}_{1} ( {b}_{j} )}{{f}_{2} ( {D}_{i , j} )} ) / ( {\sum }_{j} \frac{I ( {d}_{j} )}{{f}_{2} ( {D}_{i , j} )} ) \qquad Equation 1$$
where S(dᵢ) is the weighted average value, dᵢ is the target semiconductor chip (i being a positive integer), dⱼ is the peripheral semiconductor chip (j being a positive integer), bⱼ is a test result value, D_{i,j} is the distance value, I(dⱼ) is a single-bit value indicating whether the test result value is missing, f₁(bⱼ) is a first function having a negative second derivative function and increasing as bⱼ increases, and f₂(D_{i,j}) is a second function that increases as D_{i,j} increases.

10. The device of claim 9, wherein the first function f₁(bⱼ) is a log function as represented in Equation 2 below,
$${f}_{1} ( {b}_{j} ) = {log}_{k} ( {b}_{j} + α ) \qquad Equation 2$$
where k is a positive number and a is an offset value.

11. The device of claim 9, wherein the second function f₂(D_{i,j}) is an exponential function as represented in Equation 3 below,
$${f}_{2} ( {D}_{i , j} ) = {s}_{x}^{{D}_{i , j}} \qquad Equation 3$$
where sₓ corresponds to a peripheral range including the peripheral semiconductor chip and is an exponent that is greater than 1, wherein the peripheral range is reduced as sₓ increases, and the peripheral range increases as sₓ is reduced.

12. The device of claim 1, wherein the processor further executes the instructions to cause the processor to:
generate two-dimensional distance maps according to each of at least two two-dimensional coordinate systems among a Cartesian coordinate system, a polar coordinate system, and a photo shot coordinate system indicating a position of a photo shot in a photomask,
calculate a weighted average value for each of the two-dimensional distance maps based on distance values of each of the two-dimensional distance maps and test result values of the test result map, and
extract a greatest value of the weighted average values as the potential failure risk value.

13. A method comprising:
inspecting a wafer including a plurality of semiconductor chips by performing a test according to each of a plurality of test items;
generating a bit map including a bit value indicating whether the plurality of semiconductor chips fail at least one test item among the plurality of test items, based on an inspection result of the wafer;
generating a distance map including a distance value between a target semiconductor chip determined as an inspection pass among the plurality of semiconductor chips and one or more peripheral semiconductor chips around the target semiconductor chip in at least one coordinate system;
calculating a potential failure risk value of the target semiconductor chip based on the bit map and the distance map; and
sorting whether the target semiconductor chip has potential failure risk based on the potential failure risk value.

14-16. (canceled)

17. The method of claim 13, wherein calculating the potential failure risk value comprises calculating a weighted average value corresponding to the potential failure risk value according to Equation 4 below,
$$S ( {d}_{i} ) = ( {\sum }_{j} \frac{I ( {d}_{j} ) {f}_{1} ( {b}_{j} )}{{f}_{2} ( {D}_{i , j} )} ) / ( {\sum }_{j} \frac{I ( {d}_{j} )}{{f}_{2} ( {D}_{i , j} )} ) \qquad Equation 4$$
where S(dᵢ) is the weighted average value, dᵢ is the target semiconductor chip (i is a positive integer), dⱼ is the peripheral semiconductor chip (j is a positive integer), bⱼ is the bit value, D_{i,j} is the distance value, I(dⱼ) is a single-bit value indicating whether the bit value is missing, f₁(bⱼ) is a first function having a negative second derivative function and increasing as bⱼ increases, and f₂(D_{i,j}) is a second function that increases as D_{i,j} increases.

18. The method of claim 17, wherein the second function f₂(D_{i,j}) is an exponential function as represented in Equation 5 below,
$${f}_{2} ( {D}_{i , j} ) = {s}_{x}^{{D}_{i , j}} \qquad Equation 5$$
where sₓ is an exponent that is greater than 1.

19. (canceled)

20. The method of claim 13, wherein generating the distance map comprises:
generating a first distance map according to a Cartesian coordinate system;
generating a second distance map according to a polar coordinate system;
generating a third distance map according to a photo shot coordinate system indicating a position of a photo shot in a photomask, and
wherein calculating the potential failure risk value comprises:
calculating a first weighted average value based on distance values of the first distance map and bit values of the bit map;
calculating a second weighted average value based on distance values of the second distance map and the bit values;
calculating a third weighted average value based on distance values of the third distance map and the bit values; and
extracting a greatest value among the first weighted average value, the second weighted average value, and the third weighted average value as the potential failure risk value.

21. The method of claim 20, wherein generating the first distance map comprises:
calculating a first correction coordinate value corresponding to a ratio of a first coordinate value of each of the plurality of semiconductor chips to a first integer value indicating a greatest number of semiconductor chips arranged in the wafer in a first direction;
calculating a second correction coordinate value corresponding to a ratio of a second coordinate value of each of the plurality of semiconductor chips to a second integer value indicating a greatest number of semiconductor chips arranged in the wafer in a second direction orthogonal to the first direction; and
calculating a distance value of the first distance map based on the first correction coordinate value and the second correction coordinate value.

22. The method of claim 20, wherein generating the second distance map comprises:
calculating a first difference value between a first coordinate value of the target semiconductor chip and a first coordinate value of the peripheral semiconductor chip;
calculating a first correction difference value based on the first difference value and a correction coefficient;
calculating a second difference value between a second coordinate value of the target semiconductor chip and a second coordinate value of the peripheral semiconductor chip;
calculating a second correction difference value based on the second difference value and the correction coefficient; and
calculating a distance value of the second distance map based on the first correction difference value and the second correction difference value.

23. The method of claim 20, wherein calculating the third distance map comprises:
calculating a first distance value between a position of a first photomask corresponding to the target semiconductor chip and a position of a second photomask corresponding to the peripheral semiconductor chip;
calculating a first correction distance value based on the first distance value and a correction coefficient;
calculating a second distance value between a photo shot position of the target semiconductor chip in the first photomask and a photo shot position of the target semiconductor chip in the second photomask;
calculating a second correction distance value based on the second distance value and the correction coefficient; and
calculating a distance value of the third distance map based on the first correction distance value and the second correction distance value.

24. A method comprising:
inspecting a wafer including a plurality of semiconductor chips by performing a test according to each of a plurality of test items;
generating a defective count map including an integer value indicating a number of failed components included in a semiconductor chip that failed at least one of the plurality of test items among the plurality of semiconductor chips, based on an inspection result of the wafer;
generating a distance map including a distance value between a target semiconductor chip determined as inspection pass among the plurality of semiconductor chips and one or more peripheral semiconductor chips around the target semiconductor chip in at least one coordinate system;
calculating a potential failure risk value of the target semiconductor chip based on the defective count map and the distance map; and
sorting whether the target semiconductor chip has potential failure risk based on the potential failure risk value.

25-40. (canceled)
